(19) United States
(12) Patent Application Publication
(10) Pub. No.: US 2025/0351439 A1
(43) Pub. Date: Nov. 13, 2025

(54) COMPLEMENTARY FIELD EFFECT TRANSISTORS AND METHODS OF FORMING THE SAME

(71) Applicant: Taiwan Semiconductor Manufacturing Co., Ltd., Hsinchu (TW)

(72) Inventors: Yi-Syuan Siao, Changhua City (TW); Meng-Han Chou, Hsinchu (TW); Chien-Yu Lin, Yilan County (TW); Wei-Ting Chang, Hsinchu (TW); Tien-Shun Chang, New Taipei City (TW); Chin-I Kuan, Hsinchu (TW); Su-Hao Liu, Jhongpu Township (TW); Chi On Chui, Hsinchu (TW)

(21) Appl. No.: 19/269,971

(22) Filed: Jul. 15, 2025

Related U.S. Application Data
(63) Continuation of application No. 18/314,446, filed on May 9, 2023.
(60) Provisional application No. 63/481,826, filed on Jan. 27, 2023.

(51) Int. Cl. H10D 30/67; H10D 30/01; H10D 30/43; H10D 62/10; H10D 62/13; H10D 64/01; H10D 84/01; H10D 84/03; H10D 84/85

(52) U.S. Cl. CPC H10D 30/6729; H10D 30/014; H10D 30/43; H10D 30/6735; H10D 30/6757; H10D 62/121; H10D 62/151; H10D 64/017; H10D 84/0167; H10D 84/017; H10D 84/0184; H10D 84/038; H10D 84/85

(57) ABSTRACT

In an embodiment, a device includes: a first semiconductor nanostructure; a second semiconductor nanostructure adjacent the first semiconductor nanostructure; a first source/drain region on a first sidewall of the first semiconductor nanostructure; a second source/drain region on a second sidewall of the second semiconductor nanostructure, the second source/drain region completely separated from the first source/drain region; and a source/drain contact between the first source/drain region and the second source/drain region.

### PRIORITY CLAIM AND CROSS-REFERENCE

This application is a continuation of U.S. patent application Ser. No. 18/314,446, filed May 9, 2023, which application claims the benefit of U.S. Provisional Application No. 63/481,826, filed on Jan. 27, 2023, which applications are hereby incorporated herein by reference.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a complementary field-effect transistor (CFET) schematic in a three-dimensional view, in accordance with some embodiments.

FIGS. 2-26 are views of intermediate stages in the manufacturing of CFETs, in accordance with some embodiments.

FIGS. 27A-35 are views of intermediate stages in the manufacturing of CFETs, in accordance with some other embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

According to various embodiments, source/drain contacts are formed in source/drain recesses, adjacent to epitaxial source/drain regions in the source/drain recesses. The source/drain contacts occupy portions of the source/drain recesses that would otherwise be occupied by epitaxial source/drain regions, which are formed of doped semiconductor materials. Thus, the source/drain contacts have a large volume. The source/drain contacts are formed of a metal, which has a smaller resistance than doped semiconductor materials. Forming the source/drain contacts of a metal to a larger volume may decrease the parasitic resistance of the nanostructure-FETs, which may improve their performance.

Embodiments are described below in a particular context, specifically, a die comprising stacked nanostructure-FETs. Various embodiments may be applied, however, to dies comprising other types of transistors (e.g., unstacked nanostructure-FETs, fin field-effect transistors (FinFETs), planar transistors, or the like) in lieu of or in combination with the CFET.

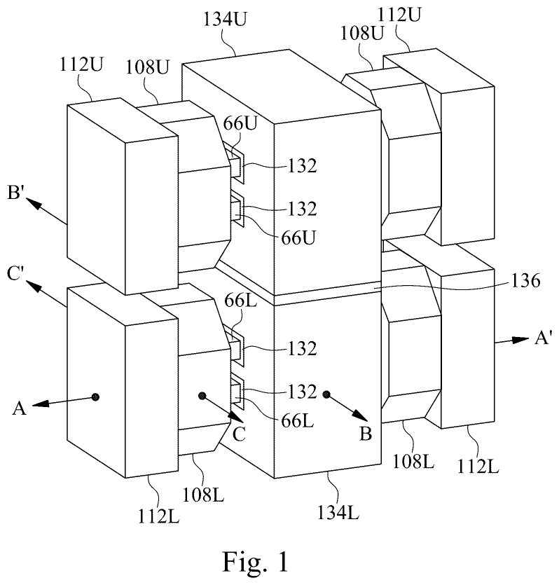

FIG. 1 illustrates an example of a CFET schematic, in accordance with some embodiments. FIG. 1 is a three-dimensional view, where some features of the CFETs are omitted for illustration clarity.

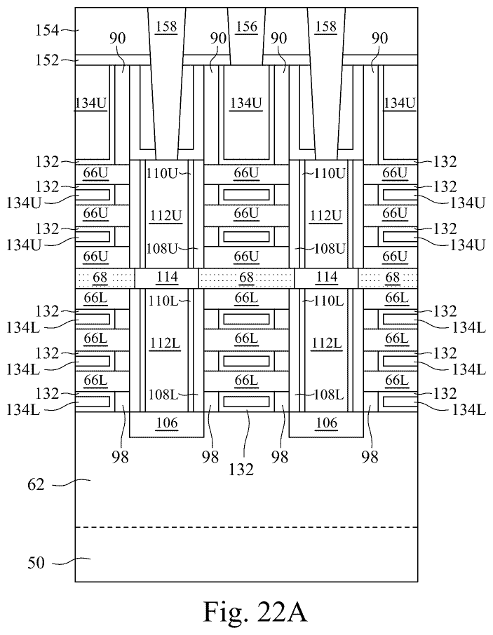

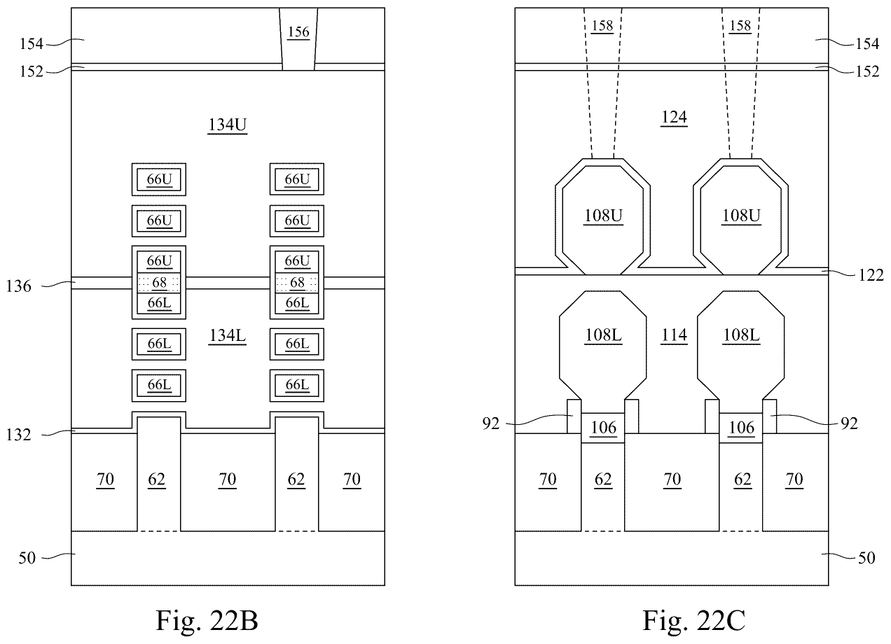

The CFETs include multiple vertically stacked nanostructure-FETs (e.g., nanowire FETs, nanosheet FETs, multi bridge channel (MBC) FETs, nanoribbon FETs, gate-all-around (GAA) FETs, or the like). For example, a CFET may include a lower nanostructure-FET of a first device type (e.g., n-type/p-type) and an upper nanostructure-FET of a second device type (e.g., p-type/n-type) that is opposite the first device type. Specifically, the CFET may include a lower PMOS transistor and an upper NMOS transistor, or the CFET may include a lower NMOS transistor and an upper PMOS transistor. Each of the nanostructure-FETs include semiconductor nanostructures 66 (including lower semiconductor nanostructures 66L and upper semiconductor nanostructures 66U), where the semiconductor nanostructures 66 act as channel regions for the nanostructure-FETs. The semiconductor nanostructures 66 may be nanosheets, nanowires, or the like. The lower semiconductor nanostructures 66L are for a lower nanostructure-FET and the upper semiconductor nanostructures 66U are for an upper nanostructure-FET. A channel isolation material (not explicitly illustrated in FIG. 1, see FIGS. 22A-22C) may be used to separate and electrically isolate the upper semiconductor nanostructures 66U from the lower semiconductor nanostructures 66L.

Gate dielectrics 132 are along top surfaces, sidewalls, and bottom surfaces of the semiconductor nanostructures 66. Gate electrodes 134 (including a lower gate electrode 134L and an upper gate electrode 134U) are over the gate dielectrics 132 and around the semiconductor nanostructures 66. Source/drain regions 108 (including lower epitaxial source/drain regions 108L and upper epitaxial source/drain regions 108U) are disposed at opposing sides of the gate dielectrics 132 and the gate electrodes 134. Source/drain region(s) 108 may refer to a source or a drain, individually or collectively dependent upon the context. Isolation features may be formed to separate desired ones of the source/drain regions 108 and/or desired ones of the gate electrodes 134. For example, a lower gate electrode 134L may optionally be separated from an upper gate electrode 134U by an isolation layer 136. Alternatively, a lower gate electrode 134L may be coupled to an upper gate electrode 134U. Further, the upper epitaxial source/drain regions 108U may be separated from lower epitaxial source/drain regions 108L by one or more dielectric layers (not explicitly illustrated in FIG. 1, see FIGS. 22A-22C). The isolation features between channel regions, gates, and source/drain regions allow for vertically stacked transistors, thereby improving device density. Because of the vertically stacked nature of CFETs, the schematic may also be referred to as stacking transistors or folding transistors.

FIG. 1 further illustrates reference cross-sections that are used in later figures. Cross-section A-A′ is parallel to a longitudinal axis of the semiconductor nanostructures 66 of a CFET and in a direction of, for example, a current flow between the source/drain regions 108 of the CFET. Cross-section B-B′ is perpendicular to cross-section A-A′ and along a longitudinal axis of a gate electrode 134 of a CFET. Cross-section C-C′ is parallel to cross-section B-B′ and extends through the source/drain regions 108 of the CFETs. Subsequent figures refer to these reference cross-sections for clarity.

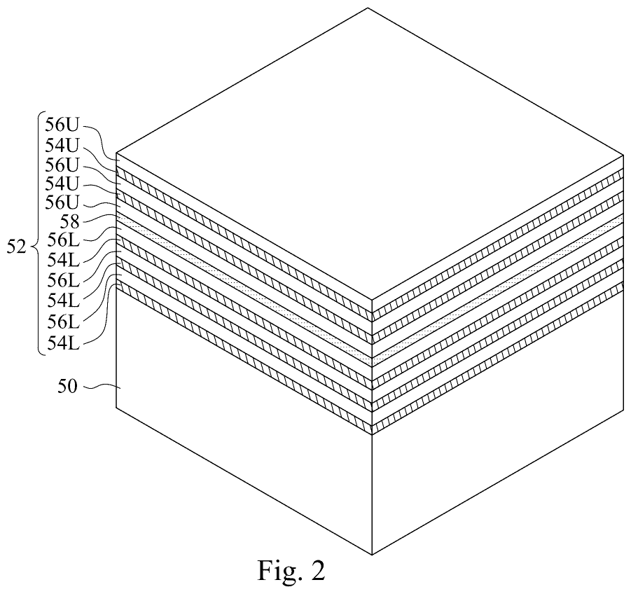

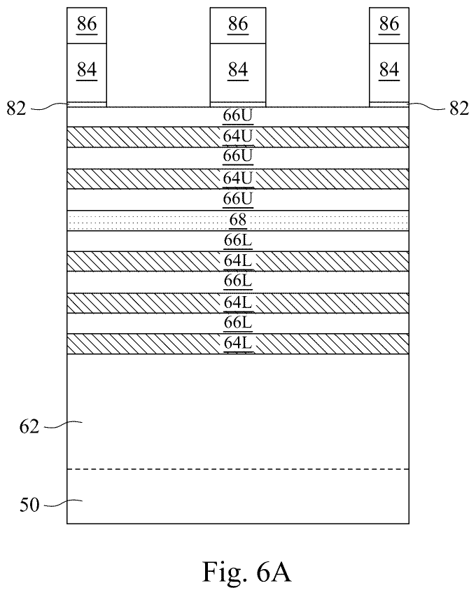

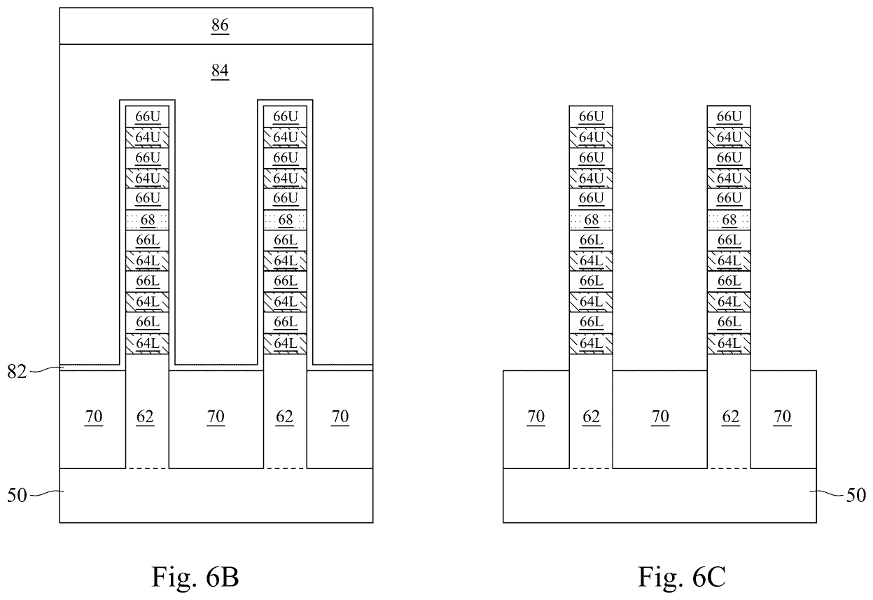

FIGS. 2-26 are views of intermediate stages in the manufacturing of CFETs, in accordance with some embodiments. FIGS. 2, 3, 4, and 5 are three-dimensional views showing a similar three-dimensional view as FIG. 1. FIGS. 6A, 7A, 8, 9, 10A, 11, 12, 13A, 14, 15A, 16, 17A, 18A, 19, 20A, 21A, 22A, 23, 24, 25, and 26 illustrate cross-sectional views along a similar cross-section as reference cross-section A-A′ in FIG. 1. FIGS. 6B, 7B, 10B, 13B, 15B, 17B, 18B, 20B, 21B, and 22B illustrate cross-sectional views along a similar cross-section as reference cross-section B-B′in FIG. 1. FIGS. 6C, 7C, 10C, 13C, 15C, 17C, 18C, 20C, 21C, and 22C illustrate cross-sectional views along a similar cross-section as reference cross-section C-C′ in FIG. 1.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

A multi-layer stack 52 is formed over the substrate 50. The multi-layer stack 52 includes alternating dummy layers 54 (including lower dummy layers 54L and upper dummy layers 54U) and semiconductor layers 56 (including lower semiconductor layers 56L and upper semiconductor layers 56U). Additionally, the multi-layer stack 52 includes an isolation layer 58. The lower dummy layers 54L and the lower semiconductor layers 56L are disposed below the isolation layer 58. The upper dummy layers 54U and the upper semiconductor layers 56U are disposed above the isolation layer 58. As subsequently described in greater detail, the dummy layers 54 will be removed and the semiconductor layers 56 will be patterned to form channel regions of CFETs. Specifically, the lower semiconductor layers 56L will be patterned to form channel regions of the lower nanostructure-FETs of the CFETs, and the upper semiconductor layers 56U will be patterned to form channel regions of the upper nanostructure-FETs of the CFETs.

The dummy layers 54 are formed of a semiconductor material, and the isolation layer 58 is formed of an insulating material. The semiconductor material may be selected from the candidate semiconductor materials of the substrate 50. The insulating material may be silicon nitride, silicon oxynitride, or the like. Other low-dielectric constant (low-k) materials having a k-value less than about 3.5 may be utilized. The semiconductor and insulating materials have a high etching selectivity to one another. As such, the material of the dummy layers 54 may be removed at a faster rate than the material of the isolation layer 58 in subsequent processing. In some embodiments, the dummy layers 54 are formed of silicon-germanium and the isolation layer 58 is formed of silicon nitride. When the dummy layers 54 are formed of silicon-germanium, they may have a germanium concentration in the range of 0% to 80%.

The semiconductor layers 56 (including the lower semiconductor layers 56L and upper semiconductor layers 56U) are formed of one or more semiconductor material(s). The semiconductor material(s) may be selected from the candidate semiconductor materials of the substrate 50. The lower semiconductor layers 56L and the upper semiconductor layers 56U may be formed of the same semiconductor material, or may be formed of different semiconductor materials. In some embodiments, the lower semiconductor layers 56L and the upper semiconductor layers 56U are both be formed of a semiconductor material suitable for p-type devices and n-type devices, such as silicon. In some embodiments, the lower semiconductor layers 56L are formed of a semiconductor material suitable for p-type devices, such as germanium or silicon-germanium, and the upper semiconductor layers 56U are formed of a semiconductor material suitable for n-type devices, such as silicon or silicon carbide. The semiconductor material(s) of the semiconductor layers 56 have a high etching selectivity to the semiconductor material of the dummy layers 54. As such, the material of the dummy layers 54 may be removed at a faster rate than the material of the semiconductor layers 56 in subsequent processing. In some embodiments, the semiconductor layers 56 are formed of silicon, which may be undoped or lightly doped at this step of processing.

The multi-layer stack 52 is illustrated as including five of the dummy layers 54 and six of the semiconductor layers 56. It should be appreciated that the multi-layer stack 52 may include any number of the dummy layers 54 and the semiconductor layers 56. The dummy layers 54 and the semiconductor layers 56 may be grown by a process such as vapor phase epitaxy (VPE) or molecular beam epitaxy (MBE), deposited by a process such as chemical vapor deposition (CVD) or atomic layer deposition (ALD), or the like. The isolation layer 58 may be deposited by a process such as chemical vapor deposition (CVD) or atomic layer deposition (ALD), or the like.

Some layers of the multi-layer stack 52 may be thicker than other layers of the multi-layer stack 52. The thickness of the isolation layer 58 may be different (e.g., greater or less) than the thickness of each of the dummy layers 54. Specifically, the isolation layer 58 has a large thickness, such as a greater thickness than each of the dummy layers 54. Forming the isolation layer 58 to a large thickness allows the isolation layer 58 to be more easily removed in subsequently processing. Additionally, the thickness of each of the semiconductor layers 56 may be different (e.g., greater or less) than the thickness(es) of each of the dummy layers 54 and/or the isolation layer 58. Specifically, each of the semiconductor layers 56 may be thicker than each of the dummy layers 54. In some embodiments, the dummy layers 54 have a thickness in the range of 2 nm to 30 nm.

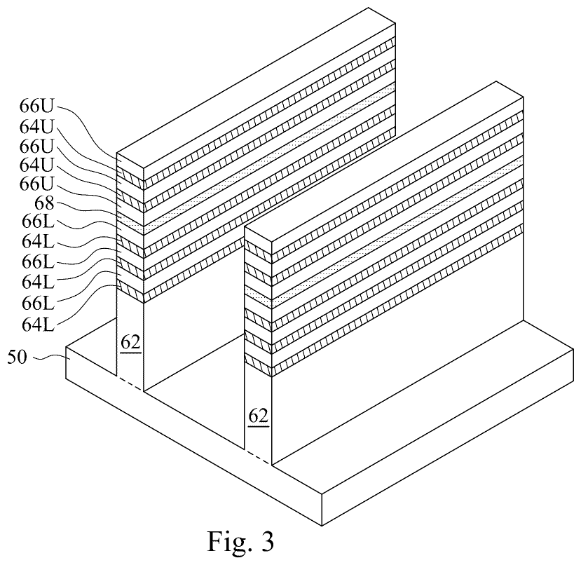

In FIG. 3, semiconductor fins 62 are formed in the substrate 50. Additionally, nanostructures 64, 66 (including lower dummy nanostructures 64L, upper dummy nanostructures 64U, lower semiconductor nanostructures 66L, and upper semiconductor nanostructures 66U) and isolation structures 68 are formed in the multi-layer stack 52. In some embodiments, the isolation structures 68, the nanostructures 64, 66 and the semiconductor fins 62 may be formed in the multi-layer stack 52 and the substrate 50 by etching trenches in the multi-layer stack 52 and the substrate 50. The etching may be any acceptable etch process, such as a reactive ion etch (RIE), neutral beam etch (NBE), the like, or a combination thereof. The etching may be anisotropic. Forming the nanostructures 64, 66 and the isolation structures 68 by etching the multi-layer stack 52 may define the lower dummy nanostructures 64L from the lower dummy layers 54L, the upper dummy nanostructures 64U from the upper dummy layers 54U, the lower semiconductor nanostructures 66L from the lower semiconductor layers 56L, the upper semiconductor nanostructures 66U from the upper semiconductor layers 56U, and the isolation structures 68 from the isolation layer 58. The lower dummy nanostructures 64L and the upper dummy nanostructures 64U may further be collectively referred to as the dummy nanostructures 64. The lower semiconductor nanostructures 66L and the upper semiconductor nanostructures 66U may further be collectively referred to as the semiconductor nanostructures 66.

As subsequently described in greater detail, various one of the nanostructures 64, 66 will be removed to form channel regions of CFETs. Specifically, the lower semiconductor nanostructures 66L will act as channel regions for lower nanostructure-FETs of the CFETs. Additionally, the upper semiconductor nanostructures 66U will act as channel regions for upper nanostructure-FETs of the CFETs. The isolation structures 68 may define boundaries of the lower nanostructure-FETs and the upper nanostructure-FETs.

The semiconductor fins 62 and the nanostructures 64, 66 may be patterned by any suitable method. For example, the semiconductor fins 62 and the nanostructures 64, 66 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the semiconductor fins 62 and the nanostructures 64, 66. In some embodiments, a mask (or other layer) may remain on the nanostructures 64, 66.

Although each of the semiconductor fins 62 and the nanostructures 64, 66 are illustrated as having a constant width throughout, in other embodiments, the semiconductor fins 62 and/or the nanostructures 64, 66 may have tapered sidewalls such that a width of each of the semiconductor fins 62 and/or the nanostructures 64, 66 continuously increases in a direction towards the substrate 50. In such embodiments, each of the nanostructures 64, 66 may have a different width and be trapezoidal in shape.

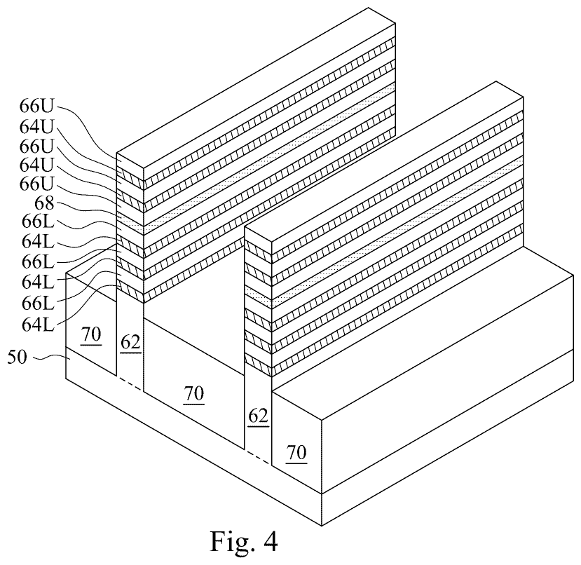

In FIG. 4, isolation regions 70 are formed adjacent the semiconductor fins 62. The isolation regions 70 may be formed by depositing an insulating material over the substrate 50, the semiconductor fins 62, and nanostructures 64, 66, and between adjacent semiconductor fins 62. The insulating material may be an oxide, such as silicon oxide, a nitride, the like, or a combination thereof, and may be formed by high-density plasma chemical vapor deposition (HDP-CVD), flowable chemical vapor deposition (FCVD), the like, or a combination thereof. Other insulating materials formed by any acceptable process may be used. In some embodiments, the insulating material is silicon oxide formed by an FCVD process. An anneal process may be performed once the insulating material is formed. In an embodiment, the insulating material is formed such that excess insulating material covers the nanostructures 64, 66. Although the insulating material is illustrated as a single layer, some embodiments may utilize multiple layers. For example, in some embodiments a liner (not separately illustrated) may first be formed along a surface of the substrate 50, the semiconductor fins 62, and the nanostructures 64, 66. Thereafter, a fill material, such as one of the previously described insulating materials may be formed over the liner.

A removal process is then applied to the insulating material to remove excess insulating material over the nanostructures 64, 66. In some embodiments, a planarization process such as a chemical mechanical polish (CMP), an etch-back process, combinations thereof, or the like may be utilized. The planarization process exposes the nanostructures 64, 66 such that top surfaces of the nanostructures 64, 66 and the insulating material are level after the planarization process is complete.

The insulating material is then recessed to form the isolation regions 70. The insulating material is recessed such that upper portions of the semiconductor fins 62 protrude from between neighboring isolation regions 70. Further, the top surfaces of the isolation regions 70 may have a flat surface as illustrated, a convex surface, a concave surface (such as dishing), or a combination thereof. The top surfaces of the isolation regions 70 may be formed flat, convex, and/or concave by an appropriate etch. The isolation regions 70 may be recessed using an etching process, such as one that is selective to the insulating material (e.g., selectively etches the insulating material at a faster rate than the materials of the semiconductor fins 62 and the nanostructures 64, 66). For example, an oxide removal using, for example, dilute hydrofluoric (dHF) acid may be used.

The previously described process is just one example of how the semiconductor fins 62 and the nanostructures 64, 66 may be formed. In some embodiments, the semiconductor fins 62 and/or the nanostructures 64, 66 may be formed using a mask and an epitaxial growth process. For example, a dielectric layer can be formed over a top surface of the substrate 50, and trenches can be etched through the dielectric layer to expose the underlying substrate 50. Epitaxial structures can be epitaxially grown in the trenches, and the dielectric layer can be recessed such that the epitaxial structures protrude from the dielectric layer to form the semiconductor fins 62 and/or the nanostructures 64, 66. The epitaxial structures may comprise the previously described alternating semiconductor materials. In some embodiments where epitaxial structures are epitaxially grown, the epitaxially grown materials may be in situ doped during growth, which may obviate prior and/or subsequent implantations, although in situ and implantation doping may be used together.

Further, appropriate wells (not separately illustrated) may be formed in the semiconductor nanostructures 66. For example, an n-type impurity implant and/or a p-type impurity implant may be performed, or the semiconductor materials may be in situ doped during growth. The n-type impurities may be phosphorus, arsenic, antimony, or the like at a concentration in a range from 10¹⁷ atoms/cm³ to 10¹⁹ atoms/cm³. The p-type impurities may be boron, boron fluoride, indium, gallium, or the like at a concentration in a range from 10¹⁷ atoms/cm³ to 10¹⁹ atoms/cm³. Other acceptable impurities such as germanium may be utilized. The wells in the lower semiconductor nanostructures 66L have a conductivity type opposite from a conductivity type of lower source/drain regions that will be subsequently formed adjacent the lower semiconductor nanostructures 66L. The wells in the upper semiconductor nanostructures 66U have a conductivity type opposite from a conductivity type of upper source/drain regions that will be subsequently formed adjacent the upper semiconductor nanostructures 66U.

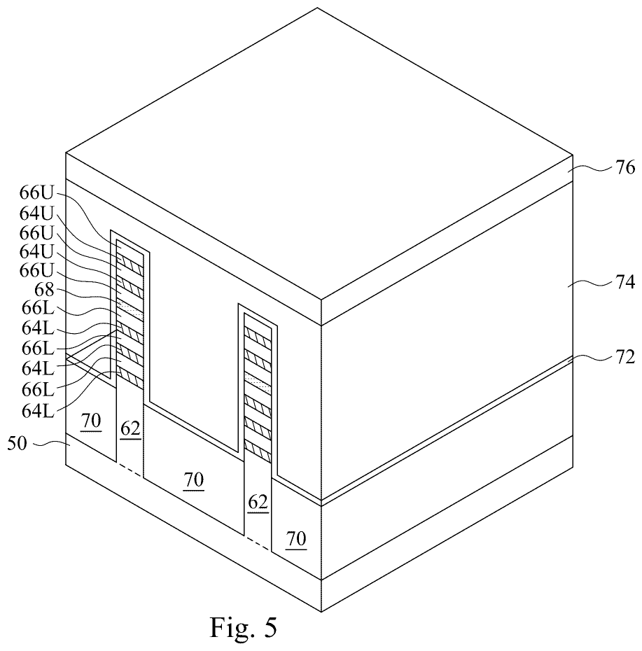

In FIG. 5, a dummy dielectric layer 72 is formed on the semiconductor fins 62 and/or the nanostructures 64, 66. The dummy dielectric layer 72 may be, for example, silicon oxide, silicon nitride, a combination thereof, or the like, and may be deposited or thermally grown according to acceptable techniques. A dummy gate layer 74 is formed over the dummy dielectric layer 72, and a mask layer 76 is formed over the dummy gate layer 74. The dummy gate layer 74 may be deposited over the dummy dielectric layer 72 and then planarized, such as by a CMP. The mask layer 76 may be deposited over the dummy gate layer 74. The dummy gate layer 74 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer 74 may be deposited by physical vapor deposition (PVD), CVD, sputter deposition, or other techniques for depositing the selected material. The dummy gate layer 74 may be formed of other materials that have a high etching selectivity to insulating materials. The mask layer 76 may include, for example, silicon nitride, silicon oxynitride, or the like. In the illustrated embodiment, the dummy dielectric layer 72 covers the isolation regions 70, such that the dummy dielectric layer 72 extends between the dummy gate layer 74 and the isolation regions 70. In another embodiment, the dummy dielectric layer 72 covers only the semiconductor fins 62 and/or the nanostructures 64, 66.

In FIGS. 6A-6C, the mask layer 76 may be patterned using acceptable photolithography and etching techniques to form masks 86. The pattern of the masks 86 then may be transferred to the dummy gate layer 74 and to the dummy dielectric layer 72 to form dummy gates 84 and dummy dielectrics 82, respectively. The dummy gates 84 cover respective channel regions of the nanostructures 64, 66. The pattern of the masks 86 may be used to physically separate each of the dummy gates 84 from adjacent dummy gates 84. The dummy gates 84 may also have a lengthwise direction substantially perpendicular to the lengthwise direction of respective semiconductor fins 62. The masks 86 can optionally be removed after patterning, such as by any acceptable etching technique.

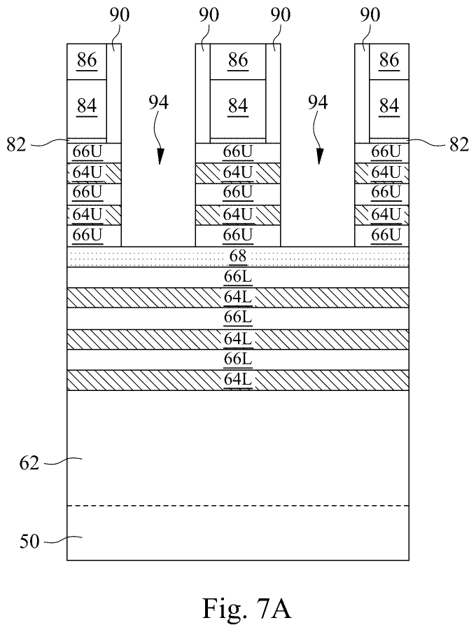

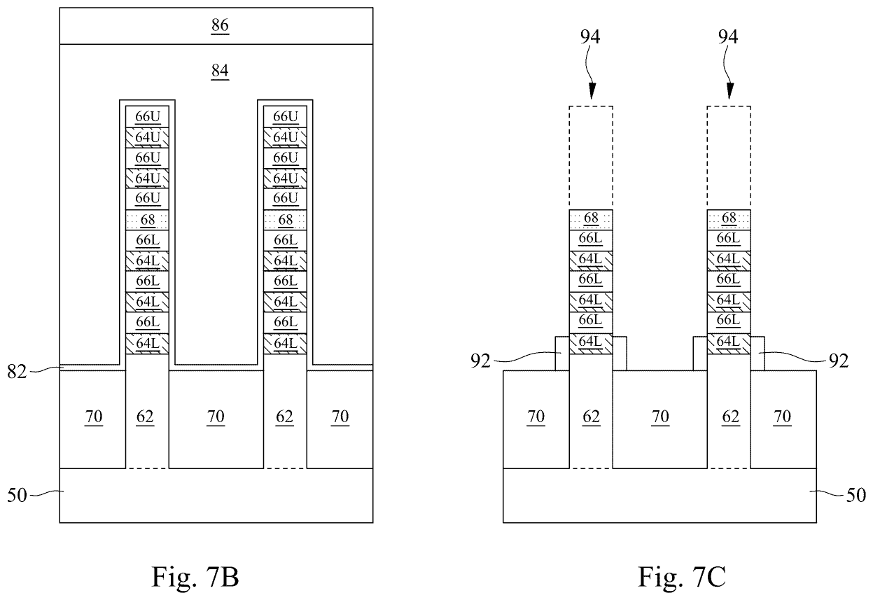

In FIGS. 7A-7C, gate spacers 90 are formed over the nanostructures 64, 66 and on exposed sidewalls of the masks 86 (if present), the dummy gates 84, and the dummy dielectrics 82. The gate spacers 90 may be formed by conformally forming one or more dielectric material(s) and subsequently etching the dielectric material(s). Acceptable dielectric materials may include silicon oxide, silicon nitride, silicon oxynitride, silicon oxycarbonitride, or the like, which may be formed by a deposition process such as chemical vapor deposition (CVD), atomic layer deposition (ALD), or the like. Other dielectric materials formed by any acceptable process may be used. Any acceptable etch process, such as a dry etch, may be performed to pattern the dielectric material(s). The etching may be anisotropic. The dielectric material(s), when etched, have portions left on the sidewalls of the dummy gates 84 (thus forming the gate spacers 90). Additionally, the dielectric material(s), when etched, may have portions left on the sidewalls of the semiconductor fins 62 and/or the nanostructures 64, 66 (thus forming fin spacers 92, see FIG. 7C).

Further, implants for lightly doped source/drain (LDD) regions (not separately illustrated) may be performed. The LDD implants may be performed before the gate spacers 90 are formed. Appropriate type impurities may be implanted into the nanostructures 64, 66 to a desired depth. The LDD regions may have a same conductivity type as a conductivity type of source/drain regions that will be subsequently formed adjacent the semiconductor nanostructures 66. Additionally, the LDD regions in the lower semiconductor nanostructures 66L may have a conductivity type opposite from a conductivity type of the LDD regions in the upper semiconductor nanostructures 66U. In some embodiments, the lower semiconductor nanostructures 66L include p-type LDD regions and the upper semiconductor nanostructures 66U include n-type LDD regions. In some embodiments, the lower semiconductor nanostructures 66L include n-type LDD regions and the upper semiconductor nanostructures 66U include p-type LDD regions. The n-type impurities may be the any of the n-type impurities previously discussed, and the p-type impurities may be the any of the p-type impurities previously discussed. The lightly doped source/drain regions may have a concentration of impurities in a range from 10¹⁷ atoms/cm³ to 10²⁰ atoms/cm³. Damage may occur during implantation. In some embodiments, the damage may occur at a depth in the range of 1 nm to 15 nm. An anneal may be used to repair implant damage and to activate the implanted impurities. In some embodiments, the grown materials of the nanostructures 64, 66 may be in situ doped during growth, which may obviate the implantations, although in situ and implantation doping may be used together.

It is noted that the previous disclosure generally describes a process of forming spacers and LDD regions. Other processes and sequences may be used. For example, fewer or additional spacers may be utilized, different sequence of steps may be utilized, additional spacers may be formed and removed, and/or the like.

Source/drain recesses 94 are formed in the upper semiconductor nanostructures 66U and the upper dummy nanostructures 64U. Epitaxial source/drain regions will be subsequently formed in the source/drain recesses 94. The source/drain recesses 94 extend through the upper semiconductor nanostructures 66U and the upper dummy nanostructures 64U to expose the isolation structures 68. The source/drain recesses 94 may be formed by etching the upper semiconductor nanostructures 66U and the upper dummy nanostructures 64U using anisotropic etching processes, such as RIE, NBE, or the like. The gate spacers 90 and the dummy gates 84 mask portions of the upper semiconductor nanostructures 66U and the upper dummy nanostructures 64U during the etching processes used to form the source/drain recesses 94. A single etch process or multiple etch processes may be used to etch each of the upper semiconductor nanostructures 66U and the upper dummy nanostructures 64U.

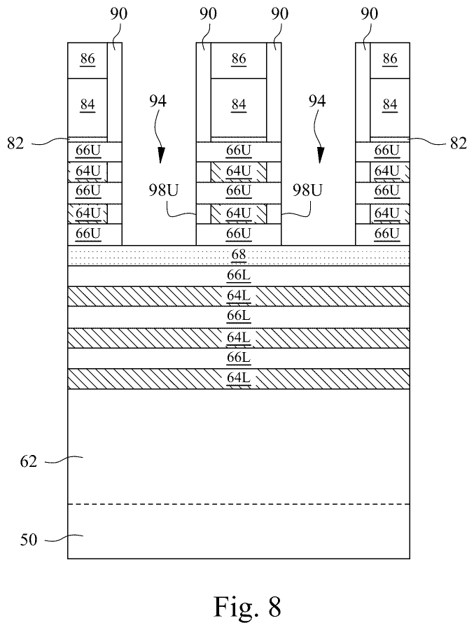

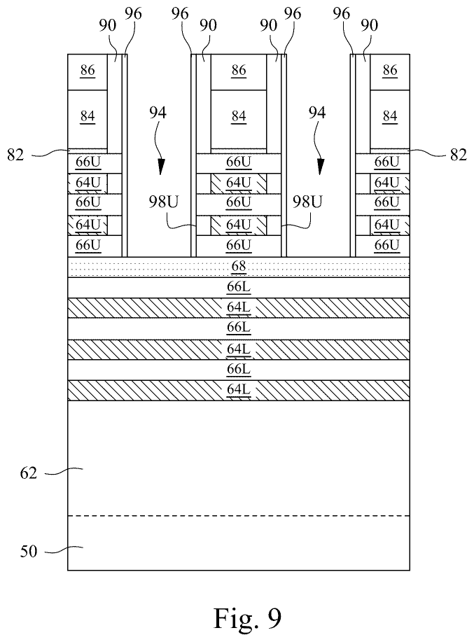

In FIG. 8, upper inner spacers 98U are formed on the sidewalls of the upper dummy nanostructures 64U. The upper inner spacers 98U are disposed on the sidewalls of the upper dummy nanostructures 64U. As will be subsequently described in greater detail, source/drain regions will be subsequently formed in the source/drain recesses 94, and the upper dummy nanostructures 64U will be subsequently replaced with corresponding gate structures. The upper inner spacers 98U act as isolation features between the subsequently formed source/drain regions and the subsequently formed gate structures. Further, the upper inner spacers 98U may be used to prevent damage to the subsequently formed source/drain regions by subsequent etch processes, such as etch processes used to subsequently remove the upper dummy nanostructures 64U.

As an example to form the upper inner spacers 98U, portions of the sidewalls of the upper dummy nanostructures 64U exposed by the source/drain recesses 94 are recessed to form sidewall recesses. The sidewalls may be recessed by any acceptable etch process, such as one that is selective to the material of the upper dummy nanostructures 64U (e.g., selectively etches the material of the upper dummy nanostructures 64U at a faster rate than the material of the upper semiconductor nanostructures 66U). The etching may be isotropic. Although sidewalls of the upper dummy nanostructures 64U are illustrated as being straight, the sidewalls may be concave or convex. An insulating material may then be conformally formed in the sidewall recesses and the source/drain recesses 94. The insulating material may be a carbon-containing dielectric material, such as silicon oxycarbonitride, silicon oxycarbide, silicon oxynitride, or the like. Other low-dielectric constant (low-k) materials having a k-value less than about 3.5 may be utilized. The insulating material of the upper inner spacers 98U has a high etching selectivity to the semiconductor material of the upper dummy nanostructures 64U. The insulating material may be formed by a deposition process, such as ALD, CVD, or the like. The insulating material may then be etched. The etching of the insulating material may be anisotropic. For example, the etch process may be a dry etch such as a RIE, a NBE, or the like. The insulating material, when etched, has portions remaining in the sidewall recesses (thus forming the upper inner spacers 98U). Although outer sidewalls of the upper inner spacers 98U are illustrated as being flush with the sidewalls of the upper semiconductor nanostructures 66U, the outer sidewalls of the upper inner spacers 98U may extend beyond or be recessed from the sidewalls of the upper semiconductor nanostructures 66U. Thus, the upper inner spacers 98U may partially fill, completely fill, or overfill the sidewall recesses. Moreover, although the sidewalls of the upper inner spacers 98U are illustrated as being straight, the sidewalls of the upper inner spacers 98U may be concave or convex.

In FIG. 9, dummy spacers 96 are formed over the isolation structures 68 and in the source/drain recesses 94. The dummy spacers 96 are disposed on the sidewalls of the upper semiconductor nanostructures 66U, the gate spacers 90, and the upper inner spacers 98U. The dummy spacers 96 may be formed by conformally forming a dielectric material and subsequently etching the dielectric material. Acceptable dielectric materials may include silicon oxide, silicon nitride, silicon oxynitride, silicon oxycarbonitride, aluminum oxide, combinations thereof, or the like, which may be formed by a deposition process such as chemical vapor deposition (CVD), atomic layer deposition (ALD), or the like. Other dielectric materials formed by any acceptable process may be used. The dielectric material of the dummy spacers 96 has a high etching selectivity to the dielectric material of the isolation structures 68. Further, although the dummy spacers 96 are each illustrated as a single layer having a uniform material composition, the dummy spacers 96 may have a multilayer structure including different layers of different dielectric materials. Any acceptable etch process, such as a dry etch, may be performed to pattern the dielectric material. The etching may be anisotropic. The etching is selective to the dummy spacers 96 (e.g., selectively etches the material of the dummy spacers 96 at a faster rate than the material of the isolation structures 68). The dielectric material, when etched, has portions left on the sidewalls of the upper semiconductor nanostructures 66U, the gate spacers 90, and the upper inner spacers 98U (thus forming the dummy spacers 96).

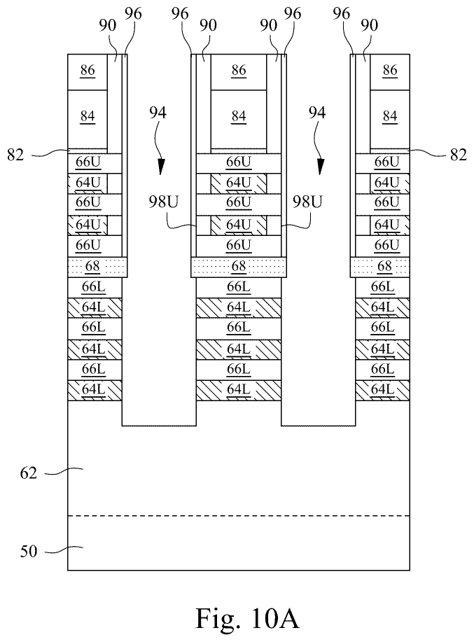

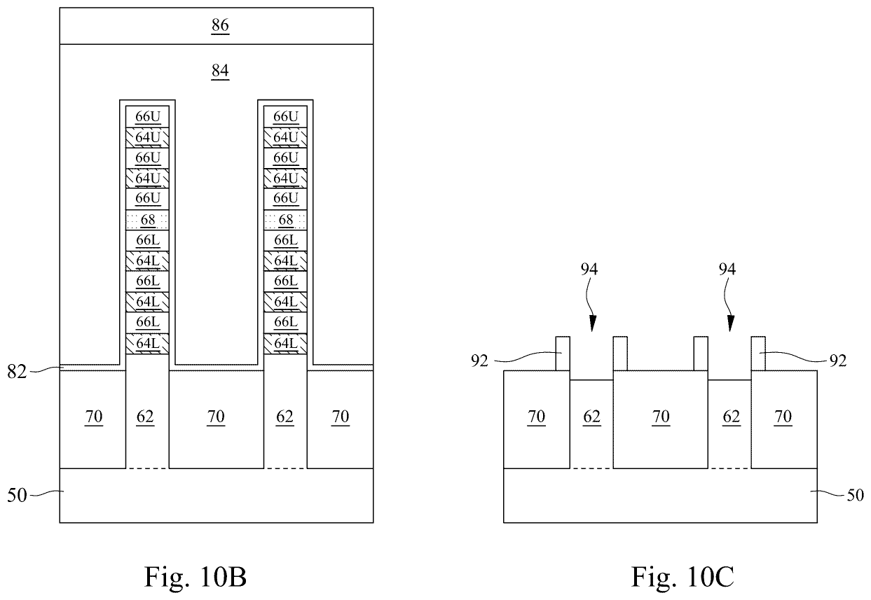

In FIGS. 10A-10C, the source/drain recesses 94 are extended into the isolation structures 68, the lower semiconductor nanostructures 66L, the lower dummy nanostructures 64L, the semiconductor fins 62, and the substrate 50. The source/drain recesses 94 may extend through the lower semiconductor nanostructures 66L and the lower dummy nanostructures 64L, and into the substrate 50. The semiconductor fins 62 may be etched such that bottom surfaces of the source/drain recesses 94 are disposed above, below, or level with the top surfaces of the isolation regions 70. In the illustrated example, the top surfaces of the isolation regions 70 are above the bottom surfaces of the source/drain recesses 94. The source/drain recesses 94 may be extended by etching the isolation structures 68, the lower semiconductor nanostructures 66L, the lower dummy nanostructures 64L, the semiconductor fins 62, and the substrate 50 using anisotropic etching processes, such as RIE, NBE, or the like. The dummy spacers 96, the gate spacers 90, and the dummy gates 84 mask portions of the isolation structures 68, the lower semiconductor nanostructures 66L, the lower dummy nanostructures 64L, the semiconductor fins 62, and the substrate 50 during the etching processes used to form the source/drain recesses 94. A single etch process or multiple etch processes may be used to etch each of the isolation structures 68, the lower semiconductor nanostructures 66L, the lower dummy nanostructures 64L, and the semiconductor fins 62. Timed etch processes may be used to stop the etching of the source/drain recesses 94 after the source/drain recesses 94 reach a desired depth. In some embodiments, the source/drain recesses 94 have a depth in the range of 30 nm to 150 nm after they are extended. Although outer sidewalls of the isolation structures 68 are illustrated as being flush with the sidewalls of the dummy spacers 96, the outer sidewalls of the isolation structures 68 may extend beyond or be recessed from the sidewalls of the dummy spacers 96. Additionally, although outer sidewalls of the lower semiconductor nanostructures 66L and the lower dummy nanostructures 64L are illustrated as being recessed from the sidewalls of the isolation structures 68, the outer sidewalls of the lower semiconductor nanostructures 66L and the lower dummy nanostructures 64L may extend beyond or be flush with the sidewalls of the isolation structures 68.

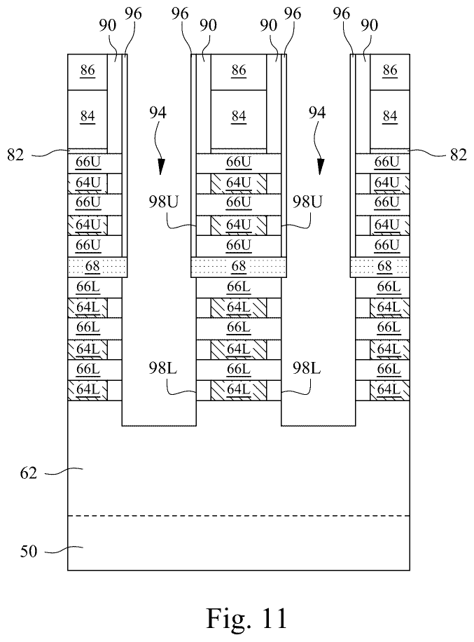

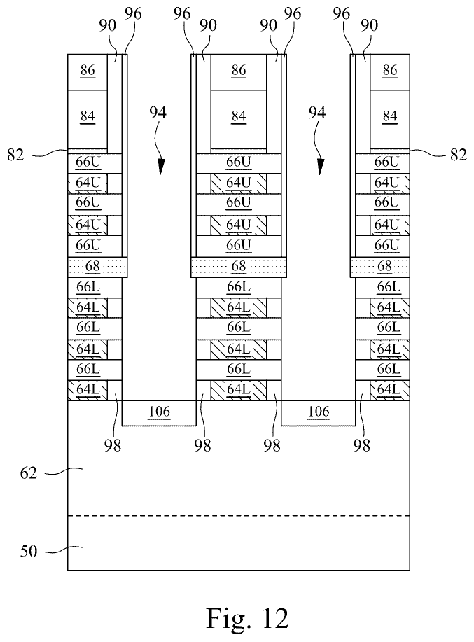

In FIG. 11, lower inner spacers 98L are formed on the sidewalls of the lower dummy nanostructures 64L. The lower inner spacers 98L are disposed on the sidewalls of the lower dummy nanostructures 64L. As will be subsequently described in greater detail, source/drain regions will be subsequently formed in the source/drain recesses 94, and the lower dummy nanostructures 64L will be subsequently replaced with corresponding gate structures. The lower inner spacers 98L act as isolation features between the subsequently formed source/drain regions and the subsequently formed gate structures. Further, the lower inner spacers 98L may be used to prevent damage to the subsequently formed source/drain regions by subsequent etch processes, such as etch processes used to subsequently remove the lower dummy nanostructures 64L.

The lower inner spacers 98L may be formed in a similar manner as the upper inner spacers 98U. For example, portions of the sidewalls of the lower dummy nanostructures 64L exposed by the source/drain recesses 94 may be recessed to form sidewall recesses, and an insulating material may be formed in the sidewall recesses. The upper inner spacers 98U and the lower inner spacers 98L may further be collectively referred to as the inner spacers 98. In some embodiments, the insulating material of the upper inner spacers 98U is the same as the insulating material of the lower inner spacers 98L. In some embodiments, the insulating material of the upper inner spacers 98U is different from the insulating material of the lower inner spacers 98L.

In FIG. 12, a stop material 106 is formed in the source/drain recesses 94 and on the semiconductor fins 62. The stop material 106 may be formed by forming a dielectric material in the source/drain recesses 94 and subsequently recessing the dielectric material. Acceptable dielectric materials may include silicon nitride, silicon oxide, silicon oxynitride, silicon oxycarbonitride, combinations thereof, or the like, which may be formed by a deposition process such as chemical vapor deposition (CVD), atomic layer deposition (ALD), or the like. Other dielectric materials formed by any acceptable process may be used. Any acceptable etch process, such as a dry etch, a wet etch, the like, or a combination thereof, may be performed to recess the dielectric material. The etching may be isotropic, such as an etch-back process that removes a desired amount of the dielectric material from the source/drain recesses 94.

Alternatively, the stop material 106 may be formed of a semiconductor material. For example, the stop material 106 may be formed of a semiconductor material selected from the candidate semiconductor materials of the substrate 50, which may be grown by an epitaxial growth process such as vapor phase epitaxy (VPE), molecular beam epitaxy (MBE), or the like. The stop material 106 may be an undoped semiconductor material. In some embodiments, the stop material 106 is formed of undoped silicon or undoped silicon-germanium.

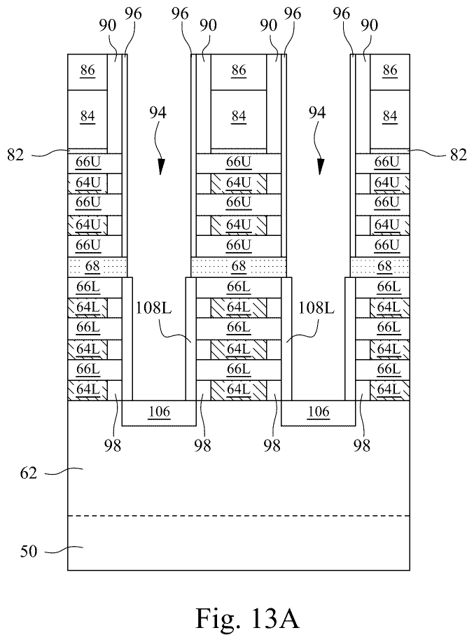

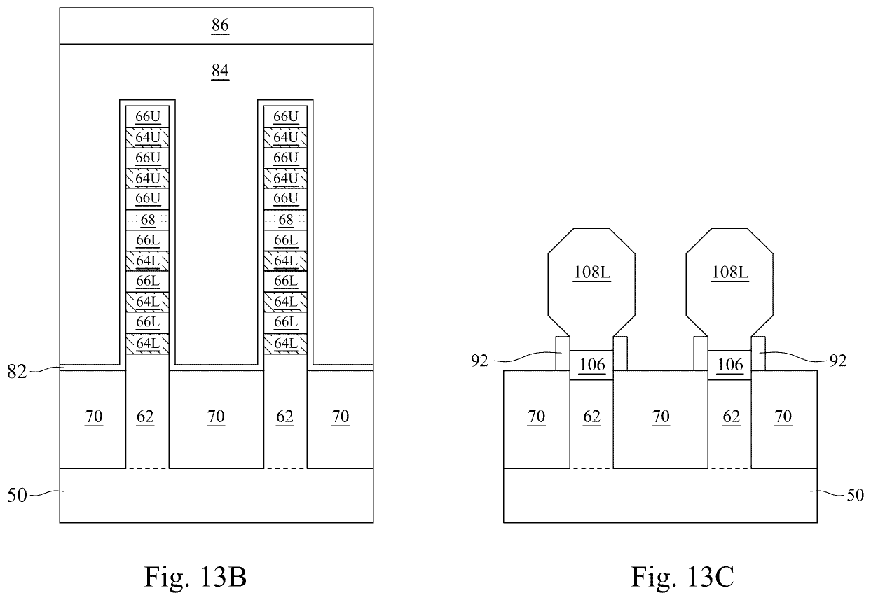

In FIGS. 13A-13C, lower epitaxial source/drain regions 108L are formed in the lower portions of the source/drain recesses 94 and on the stop material 106. The lower epitaxial source/drain regions 108L only partially fill the source/drain recesses 94, such that the lower epitaxial source/drain regions 108L are in contact with the lower semiconductor nanostructures 66L and are not in contact with the upper semiconductor nanostructures 66U. The dummy spacers 96 mask the upper semiconductor nanostructures 66U, so that the lower epitaxial source/drain regions 108L only partially fill the source/drain recesses 94 and are not formed on the upper semiconductor nanostructures 66U.

In some embodiments, the lower epitaxial source/drain regions 108L exert stress in the respective channel regions of the lower semiconductor nanostructures 66L, thereby improving performance. The lower epitaxial source/drain regions 108L are formed in the source/drain recesses 94 such that each stack of the lower semiconductor nanostructures 66L is disposed between respective neighboring pairs of the lower epitaxial source/drain regions 108L. In some embodiments, the inner spacers 98 (e.g., the lower inner spacers) are used to separate the lower epitaxial source/drain regions 108L from the lower dummy nanostructures 64L by an appropriate lateral distance so that the lower epitaxial source/drain regions 108L do not short out with subsequently formed gates of the resulting devices.

The lower epitaxial source/drain regions 108L are epitaxially grown in the lower portions of the source/drain recesses 94. For example, the lower epitaxial source/drain regions 108L may be grown laterally from exposed sidewalls of the lower semiconductor nanostructures 66L. The lower epitaxial source/drain regions 108L have a conductivity type that is suitable for the device type of the lower nanostructure-FETs. In some embodiments, the lower epitaxial source/drain regions 108L are n-type source/drain regions. For example, if the lower semiconductor nanostructures 66L are silicon, the lower epitaxial source/drain regions 108L may include materials exerting a tensile strain on the lower semiconductor nanostructures 66L, such as silicon, silicon carbide, phosphorous-doped silicon, silicon phosphide, silicon arsenide, antimony-doped silicon, combinations thereof, or the like. In some embodiments, the lower epitaxial source/drain regions 108L are p-type source/drain regions. For example, if the lower semiconductor nanostructures 66L are silicon-germanium, the lower epitaxial source/drain regions 108L may include materials exerting a compressive strain on the lower semiconductor nanostructures 66L, such as silicon-germanium, boron-doped silicon-germanium, gallium-doped silicon-germanium, boron-doped silicon, germanium, germanium tin, combinations thereof, or the like. The lower epitaxial source/drain regions 108L may have surfaces raised from respective upper surfaces of the lower semiconductor nanostructures 66L and may have facets.

The lower epitaxial source/drain regions 108L line the lower portions of the source/drain recesses 94, without filling the lower portions of the source/drain recesses 94. Specifically, the lower epitaxial source/drain regions 108L grow from the sidewalls of the lower semiconductor nanostructures 66L and may merge along the sidewalls of the lower inner spacers. As the lower epitaxial source/drain regions 108L grow in the source/drain recesses 94, facets may form. The growth of the lower epitaxial source/drain regions 108L is stopped before adjoining growth of the lower epitaxial source/drain regions 108L merges together in the source/drain recesses 94. Thus, the lower epitaxial source/drain regions 108L in a same source/drain recess 94 are completely separated from one another, and the stop material 106 remains exposed by the source/drain recesses 94 after the lower epitaxial source/drain regions 108L are formed. Timed growth processes may be used to stop the growth of the lower epitaxial source/drain regions 108L after the lower epitaxial source/drain regions 108L have grown a desired distance from the sidewalls of the lower semiconductor nanostructures 66L. In some embodiments, the lower epitaxial source/drain regions 108L have a thickness (measured from the sidewalls of the lower semiconductor nanostructures 66L) in the range of 1 nm to 5 nm. Although outer sidewalls of the lower epitaxial source/drain regions 108L are illustrated as extending beyond the sidewalls of the isolation structures 68, the outer sidewalls of the lower epitaxial source/drain regions 108L may be flush with or recessed from the sidewalls of the isolation structures 68.

The lower epitaxial source/drain regions 108L may be implanted with dopants to form source/drain regions, similar to the process previously discussed for forming lightly-doped source/drain regions, followed by an anneal. When the lower epitaxial source/drain regions 108L line the lower portions of the source/drain recesses 94, they are doped with a large impurity concentration so that they have a sufficient quantity of carriers for the lower nanostructure-FETs to operate. The source/drain regions may have an impurity concentration in the range of 1*10²¹ atoms/cm³ and 1*10²² atoms/cm³ when the lower epitaxial source/drain regions 108L have a thickness in the range of 1 nm to 5 nm. The n-type and/or p-type impurities for source/drain regions may be any of the impurities previously discussed. In some embodiments, the lower epitaxial source/drain regions 108L are in situ doped during growth.

As a result of the epitaxy processes used to form the lower epitaxial source/drain regions 108L, upper surfaces of the lower epitaxial source/drain regions 108L have facets which expand laterally outward beyond sidewalls of the nanostructures 64, 66. In some embodiments, adjacent lower epitaxial source/drain regions 108L remain separated after the epitaxy process is completed as illustrated by FIG. 13C. In other embodiments, these facets cause adjacent lower epitaxial source/drain regions 108L of a same nanostructure-FET to merge (not separately illustrated). In the illustrated embodiments, the fin spacers 92 are formed on a top surface of the isolation regions 70, thereby blocking the epitaxial growth. In some other embodiments, the fin spacers 92 may cover portions of the sidewalls of the nanostructures 64, 66 and/or the semiconductor fins 62, further blocking the epitaxial growth. In another embodiment, the spacer etch used to form the gate spacers 90 is adjusted to not form the fin spacers 92, so as to allow the lower epitaxial source/drain regions 108L to extend to the surface of the isolation regions 70.

The lower epitaxial source/drain regions 108L may comprise one or more semiconductor layers. For example, the lower epitaxial source/drain regions 108L may comprise a first semiconductor layer, a second semiconductor layer, and a third semiconductor layer. Any number of semiconductor layers may be used for the lower epitaxial source/drain regions 108L. Each of the first semiconductor layer, the second semiconductor layer, and the third semiconductor layer may be formed of different semiconductor materials and may be doped to different dopant concentrations. In some embodiments, the first semiconductor layer may have a dopant concentration less than the second semiconductor layer and greater than the third semiconductor layer. In embodiments in which the lower epitaxial source/drain regions 108L comprise three semiconductor layers, the first semiconductor layer may be grown from semiconductor features (e.g., the lower semiconductor nanostructures 66L), the second semiconductor layer may be grown on the first semiconductor layer, and the third semiconductor layer may be grown on the second semiconductor layer.

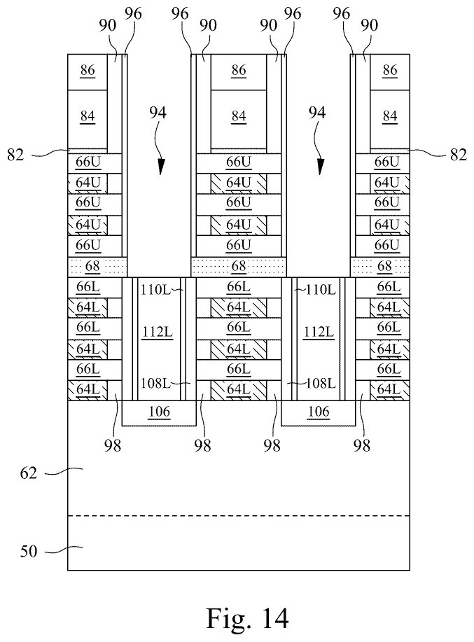

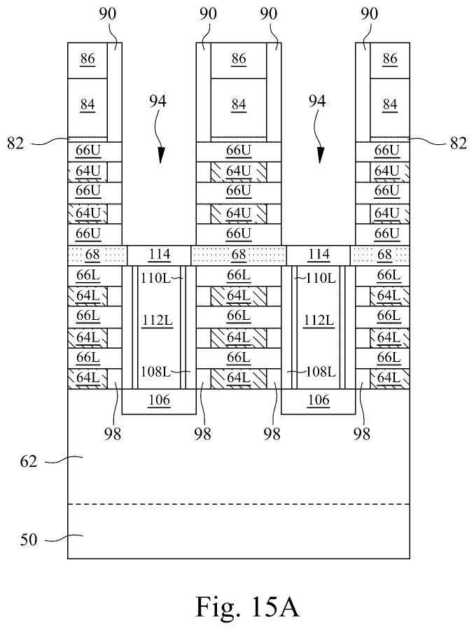

In FIG. 14, lower source/drain contacts 112L are formed in the lower portions of the source/drain recesses 94 and on the stop material 106. The lower source/drain contacts 112L are adjacent to the lower epitaxial source/drain regions 108L. A lower source/drain contact 112L in a source/drain recesses 94 may be disposed between the lower epitaxial source/drain regions 108L in the source/drain recesses 94, such that the lower source/drain contact 112L completely separates the lower epitaxial source/drain regions 108L. The lower source/drain contacts 112L may be physically and electrically coupled to the lower epitaxial source/drain regions 108L.

The lower source/drain contacts 112L may be formed by forming a conductive material in the source/drain recesses 94 and subsequently recessing the conductive material. The conductive material may be cobalt, tungsten, copper, a copper alloy, silver, gold, aluminum, nickel, or the like, which may be formed by a deposition process such as PVD, CVD, or the like. Any acceptable etch process, such as a dry etch, a wet etch, the like, or a combination thereof, may be performed to recess the conductive material. The etching may be isotropic, such as an etch-back process that removes a desired amount of the conductive material from the source/drain recesses 94. Additionally, the conductive material may be patterned so that adjacent lower epitaxial source/drain regions 108L are not shorted. The remaining conductive material forms the lower source/drain contacts 112L in the source/drain recesses 94.

The lower source/drain contacts 112L may occupy a majority of the lower portions of the source/drain recesses 94. Specifically, the lower source/drain contacts 112L occupy portions of the lower portions of the source/drain recesses 94 that would otherwise be occupied by epitaxial source/drain regions, which are formed of doped semiconductor materials. Thus, the lower source/drain contacts 112L have a larger volume as compared to filling the lower portions of the source/drain recesses 94 with epitaxial source/drain regions. The lower source/drain contacts 112L are formed of a metal, which has a smaller resistance than doped semiconductor materials. Forming the lower source/drain contacts 112L of a metal having a larger volume may decrease the parasitic resistance of the lower nanostructure-FETs, which may improve the performance of the CFETs.

The lower epitaxial source/drain regions 108L have a smaller volume as compared to filling the lower portions of the source/drain recesses 94 with epitaxial source/drain regions. As previously noted, the lower epitaxial source/drain regions 108L are doped with a large impurity concentration. Doping the lower epitaxial source/drain regions 108L with a large impurity concentration helps the lower epitaxial source/drain regions 108L have a sufficient quantity of carriers for the lower nanostructure-FETs to operate, even when the lower epitaxial source/drain regions 108L have a smaller volume.

The lower source/drain contacts 112L are formed of material(s) that are suitable for the device type of the lower nanostructure-FETs. For example, the lower source/drain contacts 112L may include one or more contact material(s) that are suitable for contacts to the lower epitaxial source/drain regions 108L of the lower nanostructure-FETs. In some embodiments, the lower source/drain contacts 112L include a contact material such as tungsten, cobalt, molybdenum, ruthenium, or the like.

Optionally, lower metal-semiconductor alloy regions 110L are formed at the interfaces between the lower epitaxial source/drain regions 108L and the lower source/drain contacts 112L. The lower metal-semiconductor alloy regions 110L are disposed on the stop material 106. The lower metal-semiconductor alloy regions 110L can be silicide regions formed of a metal silicide (e.g., titanium silicide, cobalt silicide, nickel silicide, etc.), germanide regions formed of a metal germanide (e.g. titanium germanide, cobalt germanide, nickel germanide, etc.), silicon-germanide regions formed of both a metal silicide and a metal germanide, or the like. The lower metal-semiconductor alloy regions 110L can be formed before the lower source/drain contacts 112L by depositing a metal in the source/drain recesses 94 and then performing a thermal anneal process. The metal can be any metal capable of reacting with the semiconductor materials (e.g., silicon, silicon-germanium, germanium, etc.) of the lower epitaxial source/drain regions 108L to form a low-resistance metal-semiconductor alloy, such as nickel, cobalt, titanium, tantalum, platinum, tungsten, other noble metals, other refractory metals, rare earth metals or their alloys. The metal can be deposited by a deposition process such as ALD, CVD, PVD, or the like. After the thermal anneal process, a cleaning process, such as a wet clean, may be performed to remove any residual metal from the source/drain recesses 94, such as from surfaces of the lower metal-semiconductor alloy regions 110L and the stop material 106. The lower source/drain contacts 112L can then be formed on the sidewalls of the lower metal-semiconductor alloy regions 110L. A lower source/drain contact 112L in a source/drain recesses 94 may be disposed between the lower metal-semiconductor alloy regions 110L in the source/drain recesses 94, such that the lower source/drain contact 112L completely separates the lower metal-semiconductor alloy regions 110L.

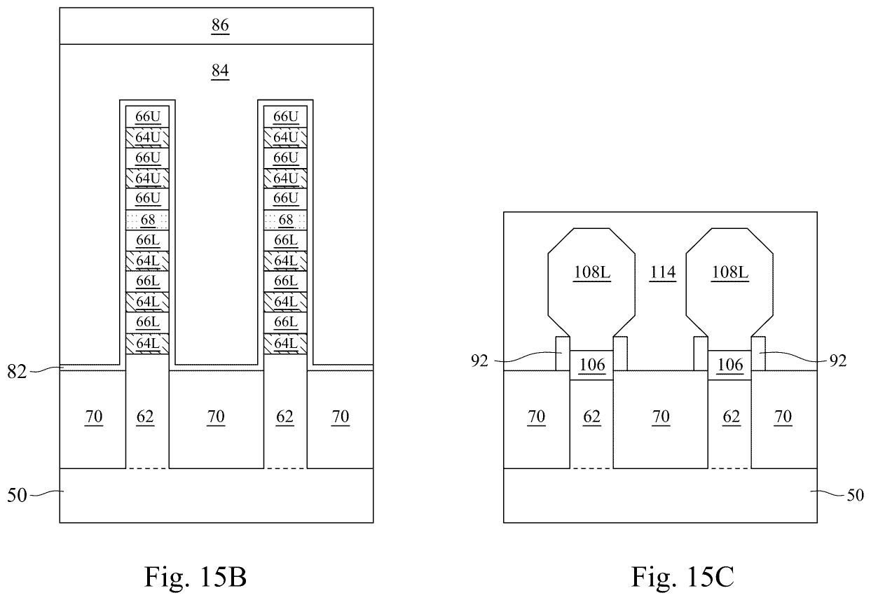

In FIGS. 15A-15C, the dummy spacers 96 are removed from the source/drain recesses 94. Any acceptable etch process, such as a dry etch, a wet etch, the like, or a combination thereof, may be performed to remove the dummy spacers 96. The etching may be isotropic. The etching is selective to the dummy spacers 96 (e.g., selectively etches the material of the dummy spacers 96 at a faster rate than the materials of the lower epitaxial source/drain regions 108L and the isolation structures 68). Removing the dummy spacers 96 exposes the sidewalls of the upper semiconductor nanostructures 66U.

Additionally, an isolation dielectric 114 is formed on the lower source/drain contacts 112L. The isolation dielectric 114 act as isolation feature between the lower source/drain contacts 112L and subsequently formed upper source/drain contacts. The isolation dielectric 114 may be formed by conformally forming a dielectric material in the source/drain recesses 94 and subsequently recessing the dielectric material. Acceptable dielectric materials may include silicon oxide, silicon nitride, silicon oxynitride, silicon oxycarbonitride, combinations thereof, or the like, which may be formed by a deposition process such as chemical vapor deposition (CVD), atomic layer deposition (ALD), or the like. Other dielectric materials formed by any acceptable process may be used. Any acceptable etch process, such as a dry etch, a wet etch, the like, or a combination thereof, may be performed to recess the dielectric material. The etching may be isotropic, such as an etch-back process that removes the dielectric material from the upper portions of the source/drain recesses 94. The dielectric material, when etched, has portions left on the lower source/drain contacts 112L (thus forming the isolation dielectric 114). The isolation dielectric 114 may also be disposed on the lower epitaxial source/drain regions 108L and/or the lower metal-semiconductor alloy regions 110L.

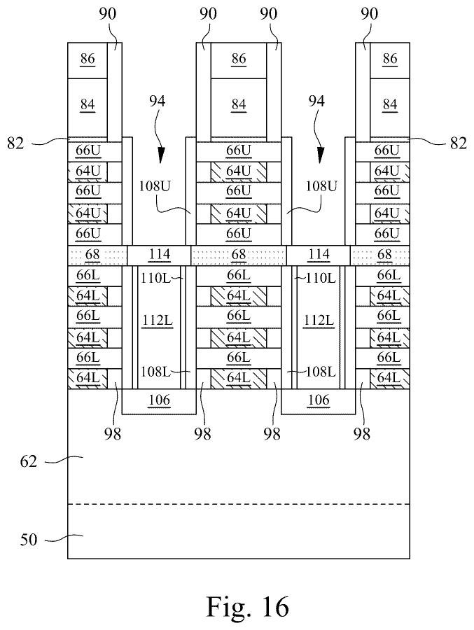

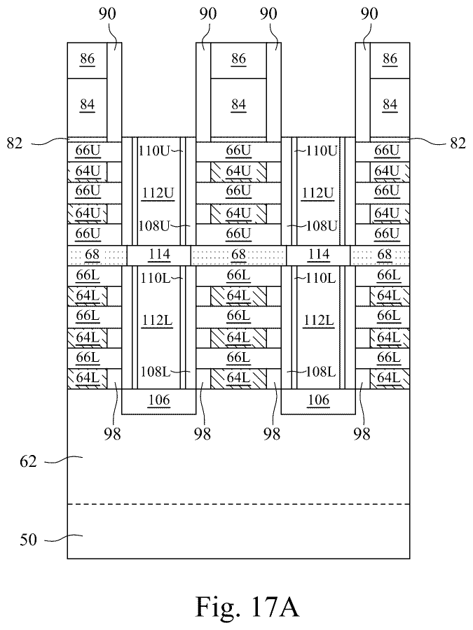

In FIG. 16, upper epitaxial source/drain regions 108U are formed in the upper portions of the source/drain recesses 94 and on the isolation dielectric 114. The upper epitaxial source/drain regions 108U only partially fill the source/drain recesses 94, such that the upper epitaxial source/drain regions 108U are in contact with the upper semiconductor nanostructures 66U and are not in contact with the lower semiconductor nanostructures 66L. The isolation dielectric 114 may provide isolation between the upper epitaxial source/drain regions 108U and the lower epitaxial source/drain regions 108L.

In some embodiments, the upper epitaxial source/drain regions 108U exert stress in the respective channel regions of the upper semiconductor nanostructures 66U, thereby improving performance. The upper epitaxial source/drain regions 108U are formed in the source/drain recesses 94 such that each stack of the upper semiconductor nanostructures 66U is disposed between respective neighboring pairs of the upper epitaxial source/drain regions 108U. In some embodiments, the inner spacers 98 (e.g., the upper inner spacers) are used to separate the upper epitaxial source/drain regions 108U from the upper dummy nanostructures 64U by an appropriate lateral distance so that the upper epitaxial source/drain regions 108U do not short out with subsequently formed gates of the resulting devices.

The upper epitaxial source/drain regions 108U are epitaxially grown in the upper portions of the source/drain recesses 94. For example, the upper epitaxial source/drain regions 108U may be grown laterally from exposed sidewalls of the upper semiconductor nanostructures 66U. The upper epitaxial source/drain regions 108U have a conductivity type that is suitable for the device type of the upper nanostructure-FETs. The conductivity type of the upper epitaxial source/drain regions 108U may be opposite the conductivity type of the lower epitaxial source/drain regions 108L. Put another way, the upper epitaxial source/drain regions 108U may be oppositely doped from the lower epitaxial source/drain regions 108L. In some embodiments, the upper epitaxial source/drain regions 108U are n-type source/drain regions. For example, if the upper semiconductor nanostructures 66U are silicon, the upper epitaxial source/drain regions 108U may include materials exerting a tensile strain on the upper semiconductor nanostructures 66U, such as silicon, silicon carbide, phosphorous-doped silicon, silicon phosphide, silicon arsenide, antimony-doped silicon, combinations thereof, or the like. In some embodiments, the upper epitaxial source/drain regions 108U are p-type source/drain regions. For example, if the upper semiconductor nanostructures 66U are silicon-germanium, the upper epitaxial source/drain regions 108U may include materials exerting a compressive strain on the upper semiconductor nanostructures 66U, such as silicon-germanium, boron-doped silicon-germanium, gallium-doped silicon-germanium, boron-doped silicon, germanium, germanium tin, combinations thereof, or the like. The upper epitaxial source/drain regions 108U may have surfaces raised from respective upper surfaces of the upper semiconductor nanostructures 66U and may have facets.

The upper epitaxial source/drain regions 108U line the upper portions of the source/drain recesses 94, without filling the upper portions of the source/drain recesses 94. Specifically, the upper epitaxial source/drain regions 108U grow from the sidewalls of the upper semiconductor nanostructures 66U and may merge along the sidewalls of the upper inner spacers. As the upper epitaxial source/drain regions 108U grow in the source/drain recesses 94, facets may form. The growth of the upper epitaxial source/drain regions 108U is stopped before adjoining growth of the upper epitaxial source/drain regions 108U merges together in the source/drain recesses 94. Thus, the upper epitaxial source/drain regions 108U in a same source/drain recess 94 are completely separated from one another, and the isolation dielectric 114 remains exposed by the source/drain recesses 94 after the upper epitaxial source/drain regions 108U are formed. Timed growth processes may be used to stop the growth of the upper epitaxial source/drain regions 108U after the upper epitaxial source/drain regions 108U have grown a desired distance from the sidewalls of the upper semiconductor nanostructures 66U. In some embodiments, the upper epitaxial source/drain regions 108U have a thickness (measured from the sidewalls of the upper semiconductor nanostructures 66U) in the range of 1 nm to 5 nm. Although outer sidewalls of the upper epitaxial source/drain regions 108U are illustrated as extending beyond the sidewalls of the isolation structures 68, the outer sidewalls of the upper epitaxial source/drain regions 108U may be flush with or recessed from the sidewalls of the isolation structures 68.

The upper epitaxial source/drain regions 108U may be implanted with dopants to form source/drain regions, similar to the process previously discussed for forming lightly-doped source/drain regions, followed by an anneal. When the upper epitaxial source/drain regions 108U line the upper portions of the source/drain recesses 94, they are doped with a large impurity concentration so that they have a sufficient quantity of carriers for the upper nanostructure-FETs to operate. The source/drain regions may have an impurity concentration in the range of 1*10²¹ atoms/cm³ and 1*10²² atoms/cm³ when the upper epitaxial source/drain regions 108U have a thickness in the range of 1 nm to 5 nm. The n-type and/or p-type impurities for source/drain regions may be any of the impurities previously discussed. In some embodiments, the upper epitaxial source/drain regions 108U are in situ doped during growth.

The upper epitaxial source/drain regions 108U may comprise one or more semiconductor layers. For example, the upper epitaxial source/drain regions 108U may comprise a first semiconductor layer, a second semiconductor layer, and a third semiconductor layer. Any number of semiconductor layers may be used for the upper epitaxial source/drain regions 108U. Each of the first semiconductor layer, the second semiconductor layer, and the third semiconductor layer may be formed of different semiconductor materials and may be doped to different dopant concentrations. In some embodiments, the first semiconductor layer may have a dopant concentration less than the second semiconductor layer and greater than the third semiconductor layer. In embodiments in which the upper epitaxial source/drain regions 108U comprise three semiconductor layers, the first semiconductor layer may be grown from semiconductor features (e.g., the upper semiconductor nanostructures 66U), the second semiconductor layer may be grown on the first semiconductor layer, and the third semiconductor layer may be grown on the second semiconductor layer.

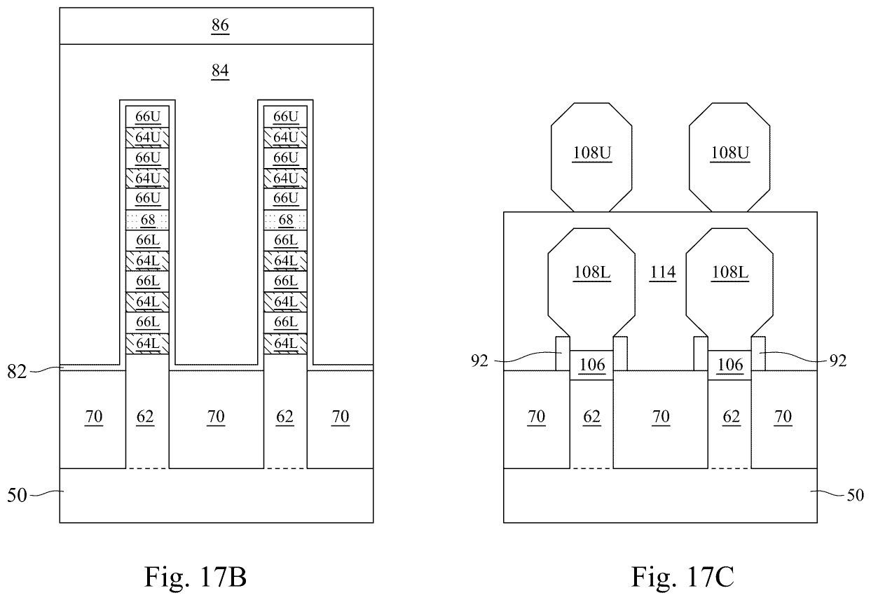

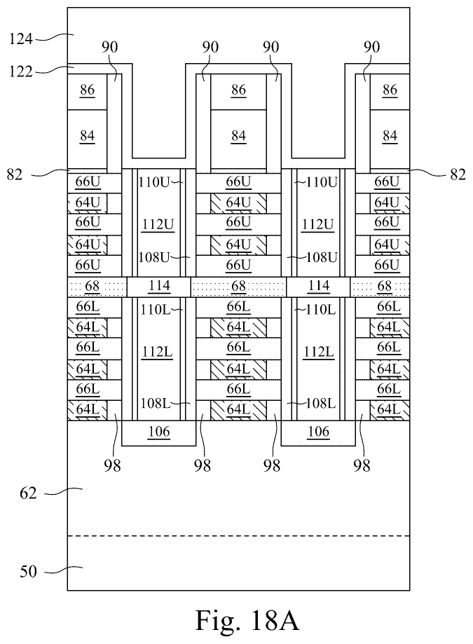

In FIGS. 17A-17C, upper source/drain contacts 112U are formed in the upper portions of the source/drain recesses 94 and on the isolation dielectric 114. The upper source/drain contacts 112U are adjacent to the upper epitaxial source/drain regions 108U. An upper source/drain contact 112U in a source/drain recesses 94 may be disposed between the upper epitaxial source/drain regions 108U in the source/drain recesses 94, such that the upper source/drain contact 112U completely separates the upper epitaxial source/drain regions 108U. The upper source/drain contacts 112U may be physically and electrically coupled to the upper epitaxial source/drain regions 108U.

The upper source/drain contacts 112U may be formed by forming a conductive material in the source/drain recesses 94 and subsequently recessing the conductive material. The conductive material may be cobalt, tungsten, copper, a copper alloy, silver, gold, aluminum, nickel, or the like, which may be formed by a deposition process such as PVD, CVD, or the like. Any acceptable etch process, such as a dry etch, a wet etch, the like, or a combination thereof, may be performed to recess the conductive material. The etching may be isotropic, such as an etch-back process that removes a desired amount of the conductive material from the source/drain recesses 94. Additionally, the conductive material may be patterned so that adjacent upper epitaxial source/drain regions 108U are not shorted. The remaining conductive material forms the upper source/drain contacts 112U in the source/drain recesses 94.

The upper source/drain contacts 112U may occupy a majority of the upper portions of the source/drain recesses 94. Specifically, the upper source/drain contacts 112U occupy portions of the upper portions of the source/drain recesses 94 that would otherwise be occupied by epitaxial source/drain regions, which are formed of doped semiconductor materials. Thus, the upper source/drain contacts 112U have a larger volume as compared to filling the upper portions of the source/drain recesses 94 with epitaxial source/drain regions. The upper source/drain contacts 112U are formed of a metal, which has a smaller resistance than doped semiconductor materials. Forming the upper source/drain contacts 112U of a metal having a larger volume may decrease the parasitic resistance of the upper nanostructure-FETs, which may improve the performance of the CFETs.

The upper epitaxial source/drain regions 108U have a smaller volume as compared to filling the upper portions of the source/drain recesses 94 with epitaxial source/drain regions. As previously noted, the upper epitaxial source/drain regions 108U are doped with a large impurity concentration. Doping the upper epitaxial source/drain regions 108U with a large impurity concentration helps the upper epitaxial source/drain regions 108U have a sufficient quantity of carriers for the upper nanostructure-FETs to operate, even when the upper epitaxial source/drain regions 108U have a smaller volume.

The upper source/drain contacts 112U are formed of material(s) that are suitable for the device type of the upper nanostructure-FETs. For example, the upper source/drain contacts 112U may include one or more contact material(s) that are suitable for contacts to the upper epitaxial source/drain regions 108U of the upper nanostructure-FETs. In some embodiments, the upper source/drain contacts 112U include a contact material such as tungsten, cobalt, molybdenum, ruthenium, or the like. The contact material(s) of the upper source/drain contacts 112U may (or may not) be different than the contact material(s) of the lower source/drain contacts 112L. The contact material(s) of the upper source/drain contacts 112U and the lower source/drain contacts 112L may be selected (e.g., to be the same or different) to tune the contact resistance to the respective source/drain regions.

Optionally, upper metal-semiconductor alloy regions 110U are formed at the interfaces between the upper epitaxial source/drain regions 108U and the upper source/drain contacts 112U. The upper metal-semiconductor alloy regions 110U are disposed on the isolation dielectric 114. The upper metal-semiconductor alloy regions 110U can be silicide regions formed of a metal silicide (e.g., titanium silicide, cobalt silicide, nickel silicide, etc.), germanide regions formed of a metal germanide (e.g. titanium germanide, cobalt germanide, nickel germanide, etc.), silicon-germanide regions formed of both a metal silicide and a metal germanide, or the like. The upper metal-semiconductor alloy regions 110U can be formed before the upper source/drain contacts 112U by depositing a metal in the source/drain recesses 94 and then performing a thermal anneal process. The metal can be any metal capable of reacting with the semiconductor materials (e.g., silicon, silicon-germanium, germanium, etc.) of the upper epitaxial source/drain regions 108U to form a low-resistance metal-semiconductor alloy, such as nickel, cobalt, titanium, tantalum, platinum, tungsten, other noble metals, other refractory metals, rare earth metals or their alloys. The metal can be deposited by a deposition process such as ALD, CVD, PVD, or the like. After the thermal anneal process, a cleaning process, such as a wet clean, may be performed to remove any residual metal from the source/drain recesses 94, such as from surfaces of the upper metal-semiconductor alloy regions 110U and the isolation dielectric 114. The upper source/drain contacts 112U can then be formed on the sidewalls of the upper metal-semiconductor alloy regions 110U. An upper source/drain contact 112U in a source/drain recesses 94 may be disposed between the upper metal-semiconductor alloy regions 110U in the source/drain recesses 94, such that the upper source/drain contact 112U completely separates the upper metal-semiconductor alloy regions 110U.

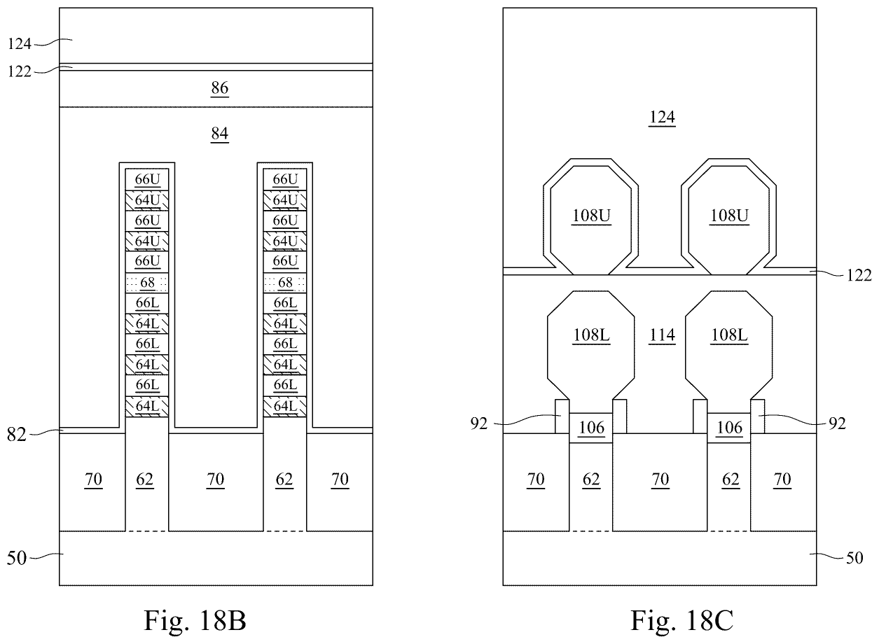

In FIGS. 18A-18C, a first inter-layer dielectric (ILD) 124 is deposited over the isolation dielectric 114, the upper source/drain contacts 112U, the gate spacers 90, and the masks 86 (if present) or the dummy gates 84. The first ILD 124 may be formed of a dielectric material, which may be deposited by any suitable method, such as CVD, plasma-enhanced chemical vapor deposition (PECVD), or FCVD. Dielectric materials may include phospho-silicate glass (PSG), boro-silicate glass (BSG), boron-doped phospho-silicate glass (BPSG), undoped silicate glass (USG), or the like. Other dielectric materials formed by any acceptable process may be used.

In some embodiments, a contact etch-stop layer (CESL) 122 is formed between the first ILD 124 and the isolation dielectric 114, the upper source/drain contacts 112U, the gate spacers 90, and the masks 86 (if present) or the dummy gates 84. The CESL 122 may be formed of a dielectric material having a high etching selectivity to the dielectric material of the first ILD 124, such as silicon nitride, silicon oxide, silicon oxynitride, or the like, which may be formed by any suitable deposition process, such as CVD, ALD, or the like. The CESL 122/first ILD 124 is disposed on the upper source/drain contacts 112U, and may also be disposed on the upper epitaxial source/drain regions 108U and/or the upper metal-semiconductor alloy regions 110U.

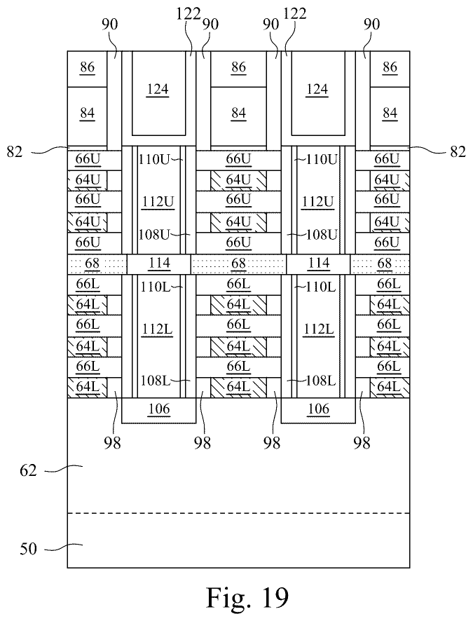

In FIG. 19, a removal process is performed to level the top surfaces of the first ILD 124 with the top surfaces of the gate spacers 90 and the masks 86 (if present) or the dummy gates 84. In some embodiments, a planarization process such as a chemical mechanical polish (CMP), an etch-back process, combinations thereof, or the like may be utilized. The planarization process may also remove the masks 86 on the dummy gates 84, and portions of the gate spacers 90 along sidewalls of the masks 86. After the planarization process, top surfaces of the first ILD 124, the gate spacers 90, and the masks 86 (if present) or the dummy gates 84 are substantially coplanar (within process variations). Accordingly, the top surfaces of the masks 86 (if present) or the dummy gates 84 are exposed through the first ILD 124. In the illustrated embodiment, the masks 86 remain after the removal process. In other embodiments, the masks 86 are removed such that the top surfaces of the dummy gates 84 are exposed through the first ILD 124.

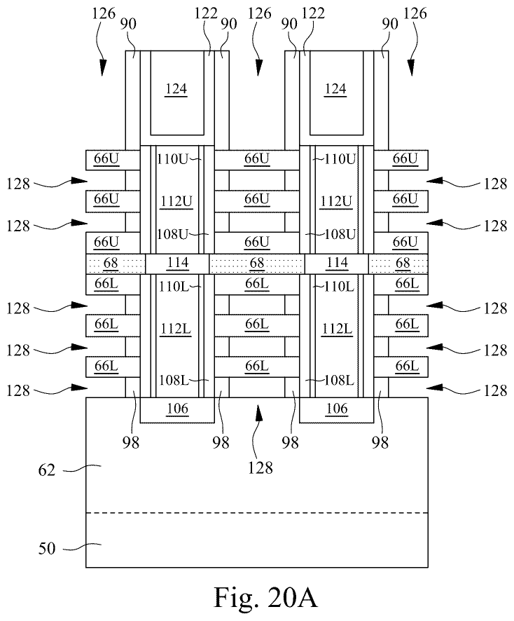

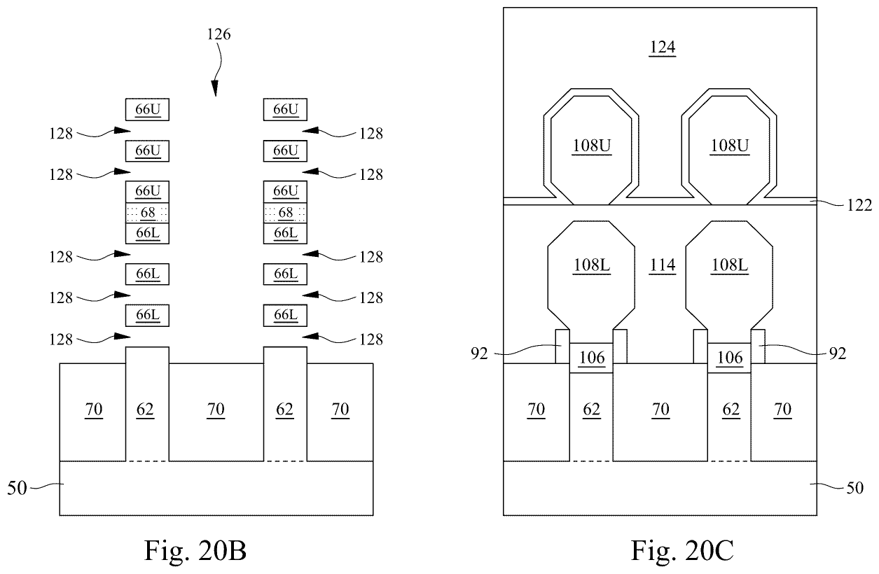

In FIGS. 20A-20C, the masks 86 (if present) and the dummy gates 84 are removed in one or more etching steps, so that recesses 126 are formed between the gate spacers 90. Portions of the dummy dielectrics 82 in the recesses 126 are also removed. In some embodiments, the dummy gates 84 and the dummy dielectrics 82 are removed by an anisotropic dry etch process. For example, the etching process may include a dry etch process using reaction gas(es) that selectively etch the material of the dummy gates 84 at a faster rate than the materials of the first ILD 124, the inner spacers 98, the gate spacers 90, and the isolation structures 68. Each recesses 126 exposes and/or overlies portions of the semiconductor nanostructures 66 which act as the channel regions in the resulting devices. The portions of the semiconductor nanostructures 66 which act as the channel regions are disposed between neighboring pairs of the lower epitaxial source/drain regions 108L or between neighboring pairs of the upper epitaxial source/drain regions 108U. During the removal, the dummy dielectrics 82 may be used as etch stop layers when the dummy gates 84 are etched. The dummy dielectrics 82 may then be removed after the removal of the dummy gates 84.

The remaining portions of the dummy nanostructures 64 are then removed to form openings 128 in regions between the semiconductor nanostructures 66. The remaining portions of the dummy nanostructures 64 can be removed by any acceptable etch process that selectively etches the material of the dummy nanostructures 64 at a faster rate than the materials of the semiconductor nanostructures 66, the isolation structures 68, and the inner spacers 98. The etching may be isotropic. For example, when the dummy nanostructures 64 are formed of silicon-germanium and the semiconductor nanostructures 66 are formed of silicon, the etch process may be a wet etch using tetramethylammonium hydroxide (TMAH), ammonium hydroxide (NH₄OH), or the like. In some embodiments, a trim process (not separately illustrated) is performed to decrease the thicknesses of the exposed portions of the semiconductor nanostructures 66 and expand the openings 128.

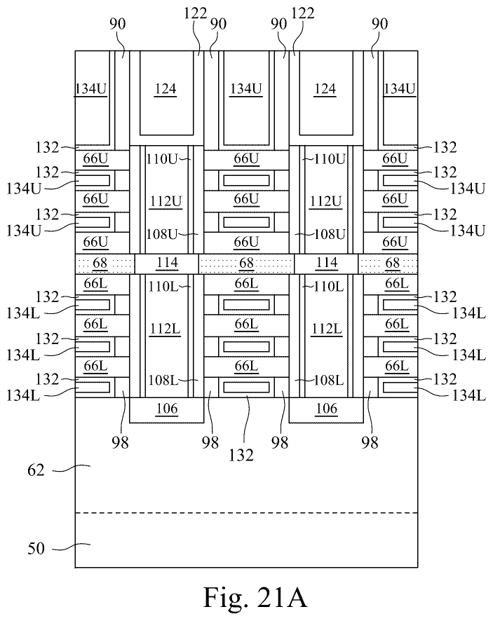

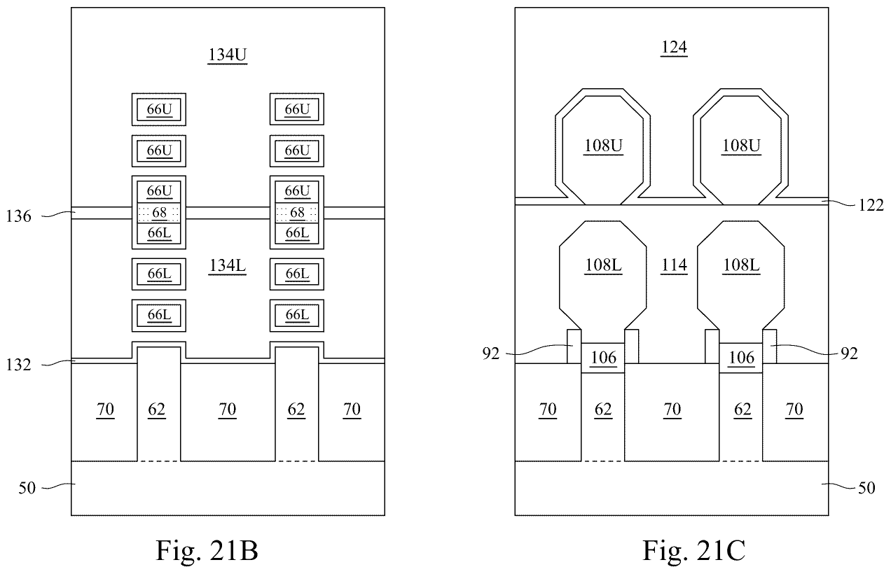

In FIGS. 21A-21C, gate dielectrics 132 and gate electrodes 134 (including lower gate electrodes 134L and upper gate electrodes 134U) are formed for replacement gates. Each respective pair of a gate dielectric 132 and a gate electrode 134 (including an upper gate electrode 134U and/or a lower gate electrode 134L) may be collectively referred to as a “gate structure.” Each gate structure extends along three sides (e.g., a top surface, a sidewall, and a bottom surface) of a channel region of a semiconductor nanostructure 66. The gate structures may also extend along sidewalls and/or a top surface of a semiconductor fin 62.

The gate dielectrics 132 include one or more gate dielectric layer(s) disposed on the sidewalls and/or the top surfaces of the semiconductor fins 62; on the top surfaces, the sidewalls, and the bottom surfaces of the channel regions of the semiconductor nanostructures 66; on the sidewalls of the inner spacers 98; and on the sidewalls of the gate spacers 90. The gate dielectrics 132 may be formed of an oxide such as silicon oxide or a metal oxide, a silicate such as a metal silicate, combinations thereof, multi-layers thereof, or the like. Additionally or alternatively, the gate dielectrics 132 may be formed of a high-k dielectric material (e.g., dielectric materials having a k-value greater than about 7.0), such as a metal oxide or a silicate of hafnium, aluminum, zirconium, lanthanum, manganese, barium, titanium, lead, and combinations thereof. The dielectric material(s) of the gate dielectrics 132 may be formed by molecular-beam deposition (MBD), ALD, PECVD, or the like. Although single-layered gate dielectrics 132 are illustrated, the gate dielectrics 132 may include any number of interfacial layers and any number of main layers. For example, the gate dielectrics 132 may include an interfacial layer and an overlying high-k dielectric layer.

The lower gate electrodes 134L include one or more gate electrode layer(s) disposed over the gate dielectrics 132 and around the lower semiconductor nanostructures 66L. The lower gate electrodes 134L are disposed in the lower portions of the recesses 126 and in the openings 128 between the lower semiconductor nanostructures 66L. The lower gate electrodes 134L may be formed of a metal-containing material such as tungsten, titanium, titanium nitride, tantalum, tantalum nitride, tantalum carbide, aluminum, ruthenium, cobalt, combinations thereof, multi-layers thereof, or the like. The lower gate electrodes 134L are formed of material(s) that are suitable for the device type of the lower nanostructure-FETs. For example, the lower gate electrodes 134L may include one or more work function tuning layer(s) formed of work function tuning material(s) that are suitable for the device type of the lower nanostructure-FETs. In some embodiments, the lower gate electrodes 134L include an n-type work function tuning layer, which may be formed of an n-type work function tuning material such as titanium aluminum, titanium aluminum carbide, tantalum aluminum, tantalum carbide, combinations thereof, or the like. In some embodiments, the lower gate electrodes 134L include a p-type work function tuning layer, which may be formed of a p-type work function tuning material such as titanium nitride, tantalum nitride, combinations thereof, or the like. Additionally or alternatively, the lower gate electrodes 134L may include a dipole-inducing element that is suitable for the device type of the lower nanostructure-FETs. Acceptable dipole-inducing elements include lanthanum, aluminum, scandium, ruthenium, zirconium, erbium, magnesium, strontium, and combinations thereof. Although single-layered gate electrodes are illustrated, the lower gate electrodes 134L may include any number of work function tuning layers, any number of barrier layers, any number of glue layers, and a fill material.

The upper gate electrodes 134U include one or more gate electrode layer(s) disposed over the gate dielectrics 132 and around the upper semiconductor nanostructures 66U. The upper gate electrodes 134U are disposed in the upper portions of the recesses 126 and in the openings 128 between the upper semiconductor nanostructures 66U. The upper gate electrodes 134U may be formed of a metal-containing material such as tungsten, titanium, titanium nitride, tantalum, tantalum nitride, tantalum carbide, aluminum, ruthenium, cobalt, combinations thereof, multi-layers thereof, or the like. The upper gate electrodes 134U are formed of material(s) that are suitable for the device type of the upper nanostructure-FETs. For example, the upper gate electrodes 134U may include one or more work function tuning layer(s) formed of work function tuning material(s) that are suitable for the device type of the upper nanostructure-FETs. In some embodiments, the upper gate electrodes 134U include an n-type work function tuning layer, which may be formed of an n-type work function tuning material such as titanium aluminum, titanium aluminum carbide, tantalum aluminum, tantalum carbide, combinations thereof, or the like. In some embodiments, the upper gate electrodes 134U include a p-type work function tuning layer, which may be formed of a p-type work function tuning material such as titanium nitride, tantalum nitride, combinations thereof, or the like. The work function tuning material(s) of the upper gate electrodes 134U may be different than the work function tuning material(s) of the lower gate electrodes 134L. Additionally or alternatively, the upper gate electrodes 134U may include a dipole-inducing element that is suitable for the device type of the upper nanostructure-FETs. Acceptable dipole-inducing elements include lanthanum, aluminum, scandium, ruthenium, zirconium, erbium, magnesium, strontium, and combinations thereof. The dipole-inducing elements of the upper gate electrodes 134U may be different than the dipole-inducing elements of the lower gate electrodes 134L. Although single-layered gate electrodes are illustrated, the upper gate electrodes 134U may include any number of work function tuning layers, any number of barrier layers, any number of glue layers, and a fill material.

In some embodiments, isolation layers 136 are formed between the lower gate electrodes 134L and the upper gate electrodes 134U. The isolation layers 136 act as isolation features between the lower gate electrodes 134L and the upper gate electrodes 134U. The isolation layers 136 may be formed of a dielectric material. Acceptable dielectric materials may include silicon oxide, silicon nitride, silicon oxynitride, silicon oxycarbonitride, combinations thereof, or the like, which may be formed by a deposition process such as chemical vapor deposition (CVD), atomic layer deposition (ALD), or the like. Other dielectric materials formed by any acceptable process may be used.

As an example to form the gate structures, one or more gate dielectric layer(s) may be deposited in the recesses 126 and the openings 128. The gate dielectric layer(s) may also be deposited on the top surfaces of the first ILD 124 and the gate spacers 90. Subsequently, one or more lower gate electrode layer(s) may be deposited on the gate dielectric layer(s), and in the remaining portions of the recesses 126 and the openings 128. The lower gate electrode layer(s) may then be recessed. Any acceptable etch process, such as a dry etch, a wet etch, the like, or a combination thereof, may be performed to recess the lower gate electrode layer(s). The etching may be isotropic, such as an etch-back process that removes the lower gate electrode layer(s) from the upper portions of the recesses 126, such that the lower gate electrode layer(s) remain in the openings 128 between the lower semiconductor nanostructures 66L. In embodiments where the isolation layers 136 are formed, a dielectric material is conformally formed on the lower gate electrode layer(s) and then recessed. Any acceptable etch process, such as a dry etch, a wet etch, the like, or a combination thereof, may be performed to recess the dielectric material. Subsequently, one or more upper gate electrode layer(s) may be deposited on the dielectric material, and in the remaining portions of the recesses 126 and the openings 128. A removal process is performed to remove the excess portions of the upper gate electrode layer(s), which excess portions are over the top surfaces of the gate spacers 90 and the first ILD 124, such that the upper gate electrode layer(s) remain in the openings 128 between the upper semiconductor nanostructures 66U. In some embodiments, a planarization process such as a chemical mechanical polish (CMP), an etch-back process, combinations thereof, or the like may be utilized. The gate dielectric layer(s), after the removal process, have portions remaining in the recesses 126 and the openings 128 (thus forming the gate dielectrics 132). The lower gate electrode layer(s), after the removal process, have portions left in the lower portions of the recesses 126 and in the openings 128 between the lower semiconductor nanostructures 66L (thus forming the lower gate electrodes 134L). The upper gate electrode layer(s), after the removal process, have portions left in the upper portions of the recesses 126 and in the openings 128 between the upper semiconductor nanostructures 66U (thus forming the upper gate electrodes 134U). The dielectric material, after the removal process, has portions left between the lower gate electrodes 134L and the upper gate electrodes 134U (thus forming the isolation layers 136). When a planarization process is utilized, the top surfaces of the gate spacers 90, the first ILD 124, the gate dielectrics 132, and the gate electrodes 134 (e.g., the upper gate electrodes 134U) are coplanar (within process variations).

In FIGS. 22A-22C, a second ILD 154 is deposited over the gate spacers 90, the first ILD 124, and the gate electrodes 134 (e.g., the upper gate electrodes 134U). In some embodiments, the second ILD 154 is a flowable film formed by a flowable CVD method, which is subsequently cured. In some embodiments, the second ILD 154 is formed of a dielectric material such as PSG, BSG, BPSG, USG, or the like, which may be deposited by any suitable method, such as CVD, PECVD, or the like.

In some embodiments, an etch stop layer (ESL) 152 is formed between the second ILD 154 and the gate spacers 90, the first ILD 124, and the gate electrodes 134 (e.g., the upper gate electrodes 134U). The ESL 152 may include a dielectric material having a high etching selectivity to the dielectric material of the second ILD 154, such as silicon nitride, silicon oxide, silicon oxynitride, or the like.

Upper gate contacts 156 and upper source/drain vias 158 (shown in ghost in FIG. 22C) are formed through the second ILD 154 to contact, respectively, the upper gate electrodes 134U and the upper source/drain contacts 112U. The upper gate contacts 156 may be physically and electrically coupled to the upper gate electrodes 134U. The upper source/drain vias 158 may be physically and electrically coupled to the upper source/drain contacts 112U.

As an example to form the upper gate contacts 156 and the upper source/drain vias 158, openings for the upper gate contacts 156 are formed through the second ILD 154 and the ESL 152, and openings for the upper source/drain vias 158 are formed through the second ILD 154, the ESL 152, the first ILD 124, and the CESL 122. The openings may be formed using acceptable photolithography and etching techniques. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be cobalt, tungsten, copper, a copper alloy, silver, gold, aluminum, nickel, or the like. A planarization process, such as a CMP, may be performed to remove excess material from the top surface of the second ILD 154. The remaining liner and conductive material form the upper gate contacts 156 and the upper source/drain vias 158 in the openings. The upper gate contacts 156 and the upper source/drain vias 158 may be formed in distinct processes, or may be formed in the same process. Although shown as being formed in the same cross-section, it should be appreciated that each of the upper gate contacts 156 and the upper source/drain vias 158 may be formed in different cross-sections, which may avoid shorting of the contacts.

As subsequently described in greater detail, a first interconnect structure (e.g., a front-side interconnect structure) will be formed over the substrate 50. Some or all of the substrate 50 will then be removed and replaced with a second interconnect structure (e.g., a back-side interconnect structure). Thus, a device layer 160 of active devices is formed between a front-side interconnect structure and a back-side interconnect structure. The front-side and back-side interconnect structures each include conductive features that are connected to the devices of the device layer 160. The conductive features (e.g., interconnects) of the front-side interconnect structure will be connected to front-sides of the upper source/drain contacts 112U and the upper gate electrodes 134U to form functional circuits, such as logic circuits, memory circuits, image sensor circuits, or the like. Some of the conductive features (e.g., interconnects) of the back-side interconnect structure will be connected to back-sides of the lower source/drain contacts 112L and the lower gate electrodes 134L to form functional circuits. Additionally, some of the conductive features (e.g., power rails) of the back-side interconnect structure will be connected to back-sides of the lower source/drain contacts 112L to provide a reference voltage, supply voltage, or the like to the functional circuits.

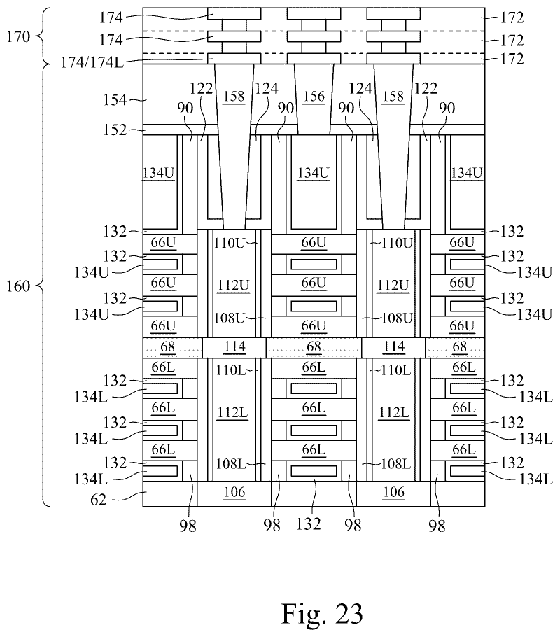

In FIG. 23, a front-side interconnect structure 170 is formed on the device layer 160, e.g., over the second ILD 154. The front-side interconnect structure 170 is referred to as a front-side interconnect structure because it is formed at a front-side of the device layer 160 (e.g., a side of the substrate 50 on which the devices are formed). The front-side interconnect structure 170 includes dielectric layers 172 and layers of conductive features 174 in the dielectric layers 172.

The dielectric layers 172 may be formed of a dielectric material. Acceptable dielectric materials include silicon oxide, phosphosilicate glass (PSG), borosilicate glass (BSG), boron-doped phosphosilicate glass (BPSG), or the like, which may be formed by CVD, ALD, or the like. The dielectric layers 172 may be formed of a low-k dielectric material having a k-value lower than about 3.0. The dielectric layers 172 may be formed of an extra-low-k (ELK) dielectric material having a k-value of less than about 2.5.

The conductive features 174 may include conductive lines and vias. The conductive vias may extend through respective ones of the dielectric layers 172 to provide vertical connections between layers of conductive lines. The conductive features 174 may be formed by a damascene process, such as a single damascene process, a dual damascene process, or the like. In a dual damascene process, a dielectric layer 172 is patterned utilizing photolithography and etching techniques to form trenches and via openings corresponding to the desired pattern of the conductive features 174. The trenches and via openings may then be filled with a conductive material. Suitable conductive materials include copper, aluminum, tungsten, cobalt, gold, combinations thereof, or the like, which may be formed by electroplating or the like.

The front-side interconnect structure 170 includes any desired number of layers of the conductive features 174. The conductive features 174 are connected to features of the underlying devices (e.g., the upper gate electrodes 134U and the upper epitaxial source/drain regions 108U) through the upper source/drain vias 158, the upper gate contacts 156, and the upper source/drain contacts 112U to form functional circuits. Thus, the conductive features 174 interconnect the upper nanostructure-FETs of the device layer 160.

After the front-side interconnect structure 170 is formed, a support substrate (not separately illustrated) may be bonded to a top surface of the front-side interconnect structure 170. The support substrate may be a glass support substrate, a ceramic support substrate, a semiconductor substrate (e.g., a silicon substrate), a wafer (e.g., a silicon wafer), or the like, which may be bonded to the front-side interconnect structure 170 by dielectric-to-dielectric bonds or the like. The support substrate may provide structural support during subsequent processing steps and in the completed device. After the support substrate is bonded to the front-side interconnect structure 170, the intermediate structure is flipped so that the back-side of the device layer 160 may be processed. The back-side of the device layer 160 refers to the side opposite to the front-side of the device layer 160 on which the front-side interconnect structure 170 is formed.

The substrate 50 is then thinned to remove at least some of the back-side portions of the substrate 50. The thinning process may include a mechanical grinding, a chemical mechanical polish (CMP), an etch back, combinations thereof, or the like. In the illustrated embodiment, the thinning process removes an entirety of the substrate 50 and portions of the semiconductor fins 62. The thinning process may be stopped on the stop material 106. In another embodiment, the thinning process removes only a portion of the substrate 50.

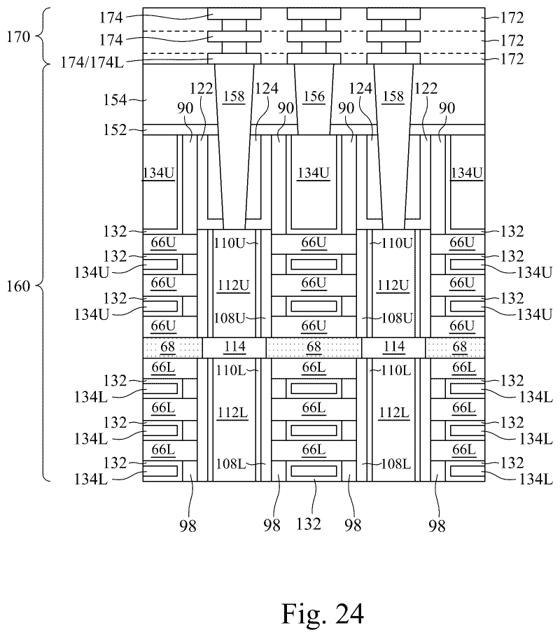

In FIG. 24, the stop material 106 and remaining portions of the semiconductor fins 62 are removed to expose the lower source/drain contacts 112L. The stop material 106 and remaining portions of the semiconductor fins 62 may be removed by etching the stop material 106 and the semiconductor fins 62. The etching may be any acceptable etch process, such as a reactive ion etch (RIE), neutral beam etch (NBE), the like, or a combination thereof. The etching may be anisotropic.

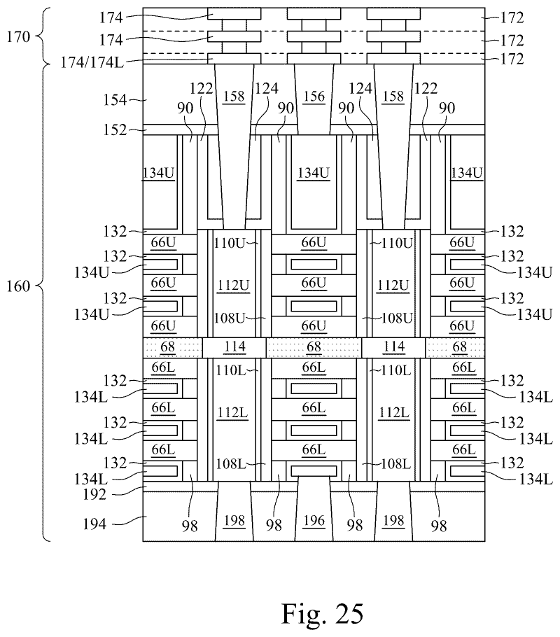

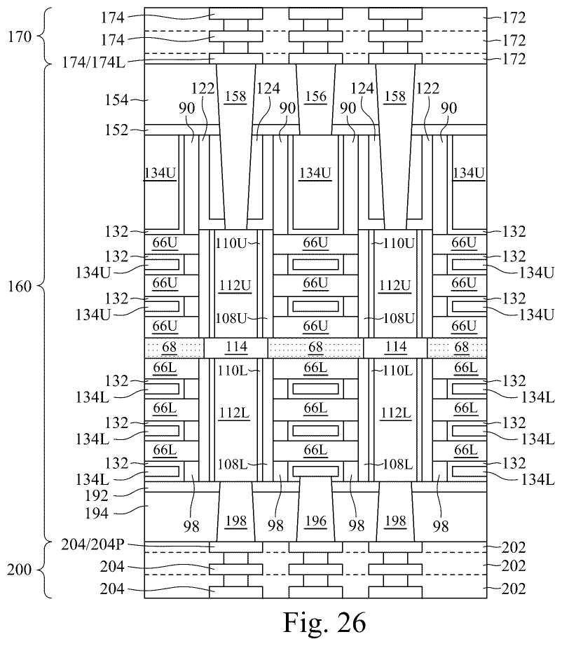

In FIG. 25, a third ILD 194 is deposited over the gate dielectrics 132, the lower source/drain contacts 112L, the lower epitaxial source/drain regions 108L, and the inner spacers 98. In some embodiments, the third ILD 194 is a flowable film formed by a flowable CVD method, which is subsequently cured. In some embodiments, the third ILD 194 is formed of a dielectric material such as PSG, BSG, BPSG, USG, or the like, which may be deposited by any suitable method, such as CVD, PECVD, or the like.

In some embodiments, an ESL 192 is formed between the third ILD 194 and the gate dielectrics 132, the lower source/drain contacts 112L, the lower epitaxial source/drain regions 108L, and the inner spacers 98. The ESL 192 may include a dielectric material having a high etching selectivity to the dielectric material of the third ILD 194, such as silicon nitride, silicon oxide, silicon oxynitride, or the like.

Lower gate contacts 196 and lower source/drain vias 198 are formed through the third ILD 194 to contact, respectively, the lower gate electrodes 134L and the lower source/drain contacts 112L. The lower gate contacts 196 may be physically and electrically coupled to the lower gate electrodes 134L. The lower source/drain vias 198 may be physically and electrically coupled to the lower source/drain contacts 112L.

As an example to form the lower gate contacts 196 and the lower source/drain vias 198, openings for the lower gate contacts 196 are formed through the third ILD 194, the ESL 192, and the gate dielectrics 132, and openings for the lower source/drain vias 198 are formed through the third ILD 194 and the ESL 192. The openings may be formed using acceptable photolithography and etching techniques. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be cobalt, tungsten, copper, a copper alloy, silver, gold, aluminum, nickel, or the like. A planarization process, such as a CMP, may be performed to remove excess material from the bottom surface of the third ILD 194. The remaining liner and conductive material form the lower gate contacts 196 and the lower source/drain vias 198 in the openings. The lower gate contacts 196 and the lower source/drain vias 198 may be formed in distinct processes, or may be formed in the same process. Although shown as being formed in the same cross-section, it should be appreciated that each of the lower gate contacts 196 and the lower source/drain vias 198 may be formed in different cross-sections, which may avoid shorting of the contacts.

In FIG. 26, a back-side interconnect structure 200 is formed on the device layer 160, e.g., over the third ILD 194. The back-side interconnect structure 200 is referred to as a back-side interconnect structure because it is formed at the back-side of the device layer 160. The back-side interconnect structure 200 includes dielectric layers 202 and layers of conductive features 204 in the dielectric layers 202.

The dielectric layers 202 may be formed of a dielectric material. Acceptable dielectric materials include silicon oxide, phosphosilicate glass (PSG), borosilicate glass (BSG), boron-doped phosphosilicate glass (BPSG), or the like, which may be formed by CVD, ALD, or the like. The dielectric layers 202 may be formed of a low-k dielectric material having a k-value lower than about 3.0. The dielectric layers 202 may be formed of an extra-low-k (ELK) dielectric material having a k-value of less than about 2.5.

The conductive features 204 may include conductive lines and vias. The conductive vias may extend through respective ones of the dielectric layers 202 to provide vertical connections between layers of conductive lines. The conductive features 204 may be formed by a damascene process, such as a single damascene process, a dual damascene process, or the like. In a dual damascene process, a dielectric layer 202 is patterned utilizing photolithography and etching techniques to form trenches and via openings corresponding to the desired pattern of the conductive features 204. The trenches and via openings may then be filled with a conductive material. Suitable conductive materials include copper, aluminum, tungsten, cobalt, gold, combinations thereof, or the like, which may be formed by electroplating or the like.

The back-side interconnect structure 200 includes any desired number of layers of the conductive features 204. Some of the conductive features 204 are connected to features of the overlying devices (e.g., the lower gate electrodes 134L and the lower epitaxial source/drain regions 108L) through the lower source/drain vias 198, the lower gate contacts 196, and the lower source/drain contacts 112L to form functional circuits. Thus, the conductive features 204 interconnect the lower nanostructure-FETs of the device layer 160. Additionally, some of the conductive features 204 form a power distribution network for the devices of the device layer 160. Some or all of the conductive features 204 are power rails 204P, which are conductive lines that electrically connect the lower epitaxial source/drain regions 108L to a reference voltage, supply voltage, or the like. By placing the power rails 204P at a back-side of the device layer 160 rather than at a front-side of the device layer 160, advantages may be achieved. For example, the back-side of the device layer 160 may accommodate wider power rails than the front-side of the device layer 160, reducing resistance and increasing efficiency of power delivery to the devices of the device layer 160. For example, a width of the conductive features 204 may be at least twice a width of a first level conductive line (e.g., conductive line 174L) of the front-side interconnect structure 170.

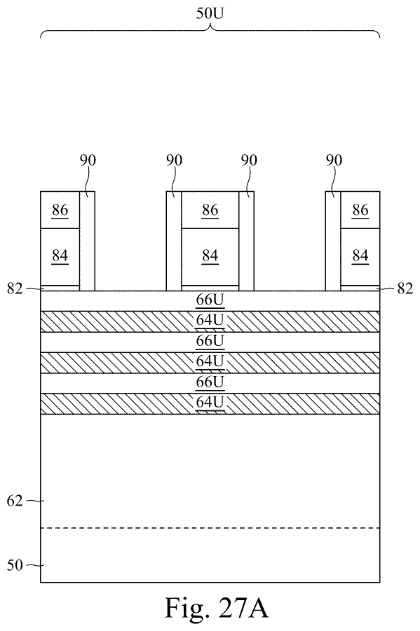

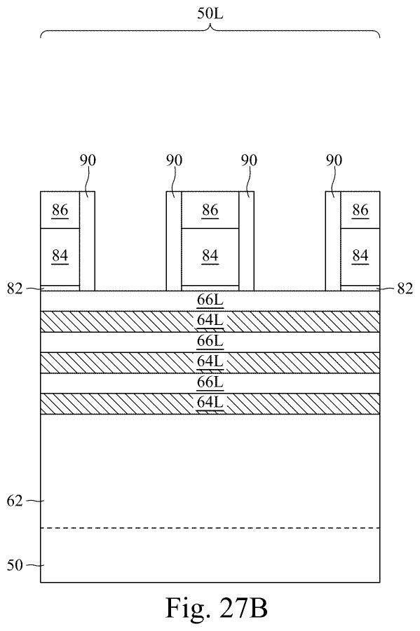

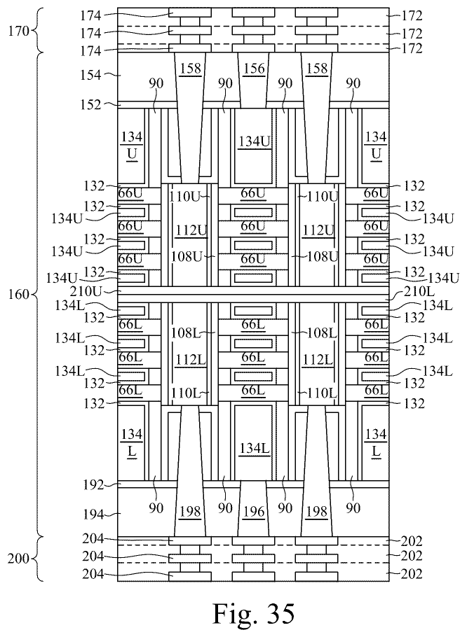

FIGS. 27A-35 are views of intermediate stages in the manufacturing of CFETs, in accordance with some other embodiments. In this embodiment, the CFETs are formed by separately processing an upper wafer 50U and a lower wafer 50L to form the upper and lower nanostructure-FETs, respectively, and then bonding the upper wafer 50U to the lower wafer 50L. FIGS. 27A, 28A, 29A, 30A, 31A, 32A, 33A, and 34A illustrate cross-sectional views of the upper wafer 50U along a similar cross-section as reference cross-section A-A′ in FIG. 1. FIGS. 27B, 28B, 29B, 30B, 31B, 32B, 33B, and 34B illustrate cross-sectional views of the lower wafer 50L along a similar cross-section as reference cross-section A-A′ in FIG. 1. FIG. 35 illustrates a cross-sectional view of the bonded wafers along a similar cross-section as reference cross-section A-A′ in FIG. 1.

In FIGS. 27A-27B, semiconductor fins 62 and nanostructures 64, 66 are formed in the upper wafer 50U and the lower wafer 50L. The semiconductor fins 62 are formed in respective substrates 50 of the upper wafer 50U and the lower wafer 50L. The semiconductor fins 62 and the nanostructures 64, 66 may be formed in a similar manner as described for FIGS. 2-3, e.g., by etching trenches in multi-layer stacks over the substrates 50. The upper wafer 50U includes upper dummy nanostructures 64U and upper semiconductor nanostructures 66U. The lower wafer 50L includes lower dummy nanostructures 64L and lower semiconductor nanostructures 66L. In this embodiment, the isolation structures 68 are omitted.

Dummy gates 84 and dummy dielectrics 82 are then formed over the nanostructures 64, 66 of the upper wafer 50U and the lower wafer 50L. The dummy gates 84 and the dummy dielectrics 82 may be formed in a similar manner as described for FIGS. 5-6C.

Gate spacers 90 are then formed over the nanostructures 64, 66 and on exposed sidewalls of the masks 86 (if present), the dummy gates 84, and the dummy dielectrics 82. The gate spacers 90 may be formed in a similar manner as described for FIGS. 7A-7C.

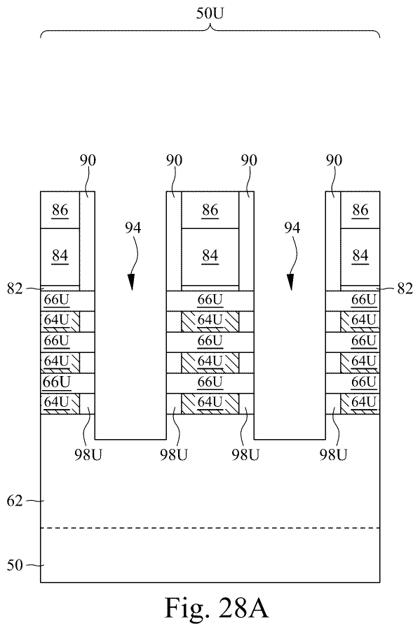

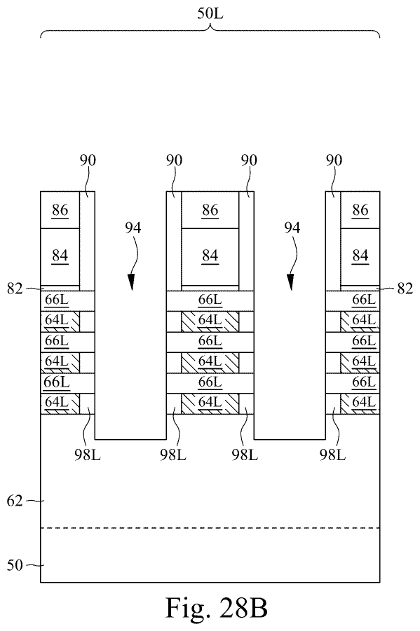

In FIGS. 28A-28B, source/drain recesses 94 are formed. The source/drain recesses 94 of the upper wafer 50U are formed in the upper semiconductor nanostructures 66U and the upper dummy nanostructures 64U. The source/drain recesses 94 of the lower wafer 50L are formed in the lower semiconductor nanostructures 66L and the lower dummy nanostructures 64L. The source/drain recesses 94 may be formed in a similar manner as described for FIGS. 7A-7C.

Inner spacers 98 are then formed on the sidewalls of the dummy nanostructures 64. Upper inner spacers 98U are formed on the sidewalls of the upper dummy nanostructures 64U of the upper wafer 50U. Lower inner spacers 98L are formed on the sidewalls of the lower dummy nanostructures 64L of the lower wafer 50L. The inner spacers 98 may be formed in a similar manner as described for FIGS. 8 and 11.

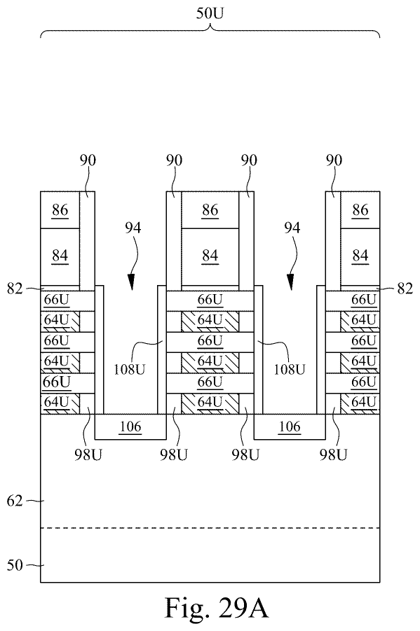

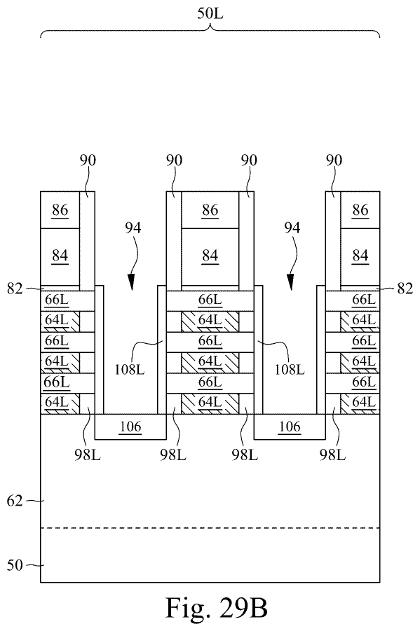

In FIGS. 29A-29B, a stop material 106 is formed in the source/drain recesses 94 of the upper wafer 50U and the lower wafer 50L. The stop material 106 may be formed in a similar manner as described for FIG. 12.

Epitaxial source/drain regions 108 are then formed in the source/drain recesses 94 and on the stop material 106. Upper epitaxial source/drain regions 108U are formed in the source/drain recesses 94 of the upper wafer 50U. Lower epitaxial source/drain regions 108L are formed in the source/drain recesses 94 of the lower wafer 50L. The epitaxial source/drain regions 108 may be formed in a similar manner as described for FIGS. 13A-13C and 16.

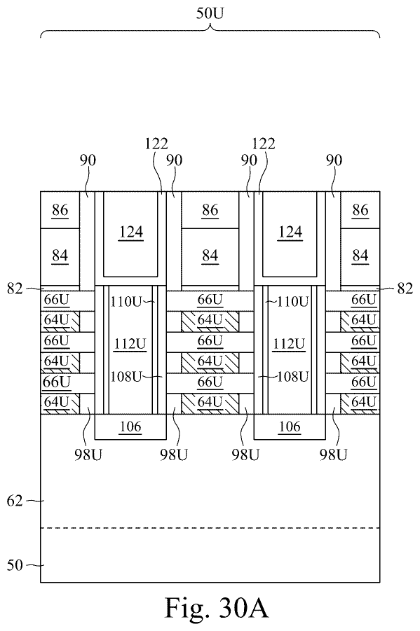

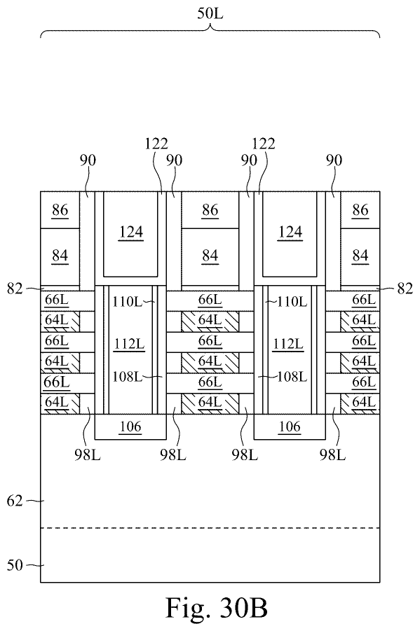

In FIGS. 30A-30B, source/drain contacts 112 are formed in the source/drain recesses 94 and on the stop material 106 and adjacent to the epitaxial source/drain regions 108. Upper source/drain contacts 112U are formed in the source/drain recesses 94 of the upper wafer 50U. Lower source/drain contacts 112L are formed in the source/drain recesses 94 of the lower wafer 50L. The source/drain contacts 112 may be formed in a similar manner as described for FIGS. 14 and 17A-17C.

Optionally, metal-semiconductor alloy regions 110 are formed at the interfaces between the epitaxial source/drain regions 108 and the source/drain contacts 112. Upper metal-semiconductor alloy regions 110U are formed at the interfaces between the upper epitaxial source/drain regions 108U and the upper source/drain contacts 112U of the upper wafer 50U. Lower metal-semiconductor alloy regions 110L are formed at the interfaces between the lower epitaxial source/drain regions 108L and the lower source/drain contacts 112L of the lower wafer 50L. The metal-semiconductor alloy regions 110 may be formed in a similar manner as described for FIGS. 14 and 17A-17C.

A first ILD 124 is deposited over the source/drain contacts 112 and the epitaxial source/drain regions 108 of the upper wafer 50U and the lower wafer 50L. In some embodiments, a CESL 122 is formed between the first ILD 124 and the source/drain contacts 112 and the epitaxial source/drain regions 108. The first ILD 124 and the CESL 122 may be formed in a similar manner as described for FIGS. 18A-18C. A removal process may be performed to level the top surfaces of the first ILD 124 with the top surfaces of the gate spacers 90 and the masks 86 (if present) or the dummy gates 84, in a similar manner as described for FIG. 19.

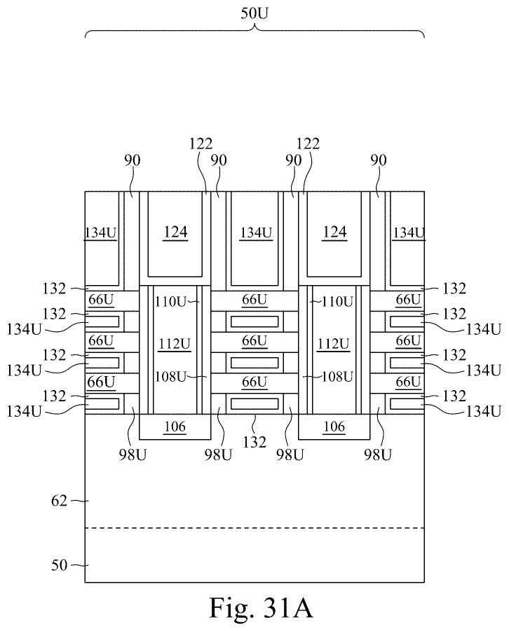

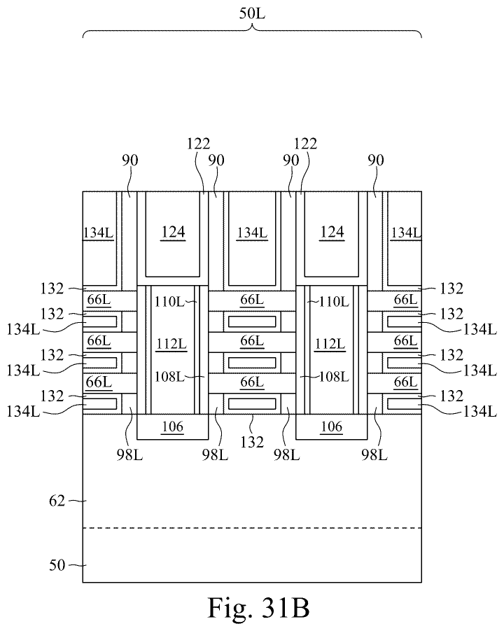

In FIGS. 31A-31B, the masks 86 (if present), the dummy gates 84, and the dummy dielectrics 82 are removed. The remaining portions of the dummy nanostructures 64 are then removed. The removal processes may be performed in a similar manner as described for FIGS. 20A-20C. Gate dielectrics 132 and gate electrodes 134 are then formed for replacement gates. Upper gate electrodes 134U are formed over the gate dielectrics 132 of the upper wafer 50U. Lower gate electrodes 134L are formed over the gate dielectrics 132 of the lower wafer 50L. The respective gate electrodes 134 may be formed in a similar manner as described for FIGS. 21A-21C.

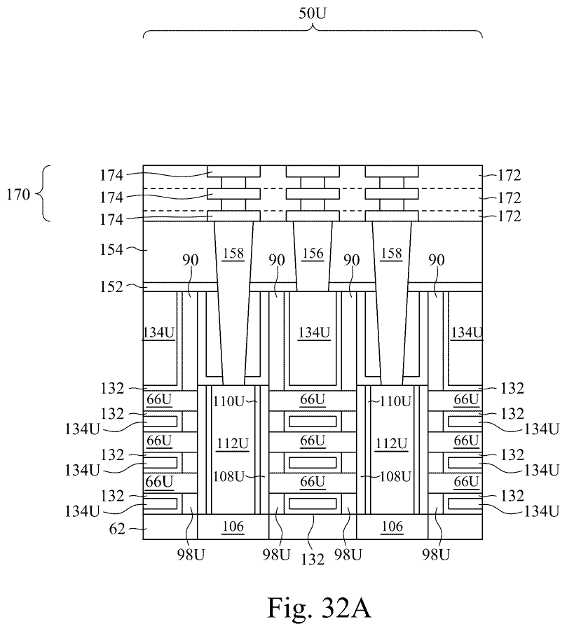

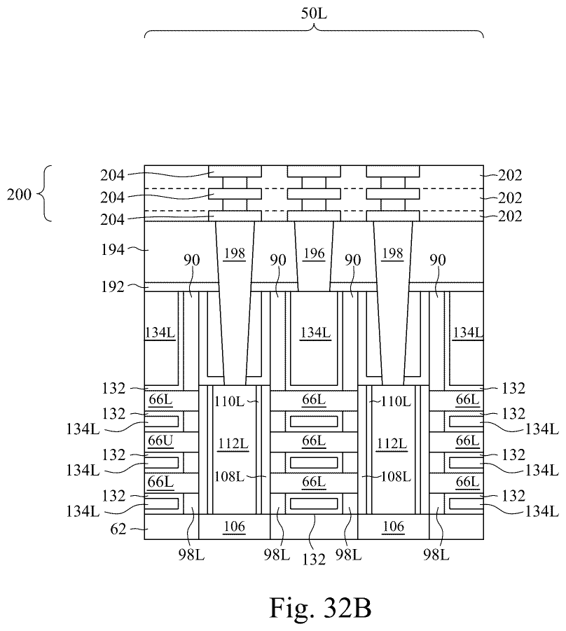

In FIGS. 32A-32B, a second ILD 154 is deposited over the gate spacers 90, the first ILD 124, and the upper gate electrodes 134U of the upper wafer 50U. In some embodiments, an ESL 152 is formed between the second ILD 154 and the gate spacers 90, the first ILD 124, and the upper gate electrodes 134U of the upper wafer 50U. The second ILD 154 and the ESL 152 may be formed in a similar manner as described for FIG. 22. Upper gate contacts 156 and upper source/drain vias 158 are formed through the second ILD 154 to contact, respectively, the upper gate electrodes 134U and the upper source/drain contacts 112U of the upper wafer 50U. The upper gate contacts 156 and the upper source/drain vias 158 may be formed in a similar manner as described for FIGS. 22A-22C. A front-side interconnect structure 170 is then formed on the second ILD 154. The front-side interconnect structure 170 may be formed in a similar manner as described for FIG. 23.

A third ILD 194 is deposited over the gate spacers 90, the first ILD 124, and the lower gate electrodes 134L of the lower wafer 50L. In some embodiments, an ESL 192 is formed between the third ILD 194 and the gate spacers 90, the first ILD 124, and the lower gate electrodes 134L of the lower wafer 50L. The third ILD 194 and the ESL 192 may be formed in a similar manner as described for FIG. 25. Lower gate contacts 196 and lower source/drain vias 198 are formed through the third ILD 194 to contact, respectively, the lower gate electrodes 134L and the lower source/drain contacts 112L of the lower wafer 50L. The lower gate contacts 196 and the lower source/drain vias 198 may be formed in a similar manner as described for FIG. 25. A back-side interconnect structure 200 is then formed on the third ILD 194. The back-side interconnect structure 200 may be formed in a similar manner as described for FIG. 26.

The substrates 50 of the upper wafer 50U and the lower wafer 50L are thinned to remove at least some of the back-side portions of the substrates 50. The thinning processes may be stopped on the stop material 106. The thinning processes may be performed in a similar manner as described for FIG. 23.

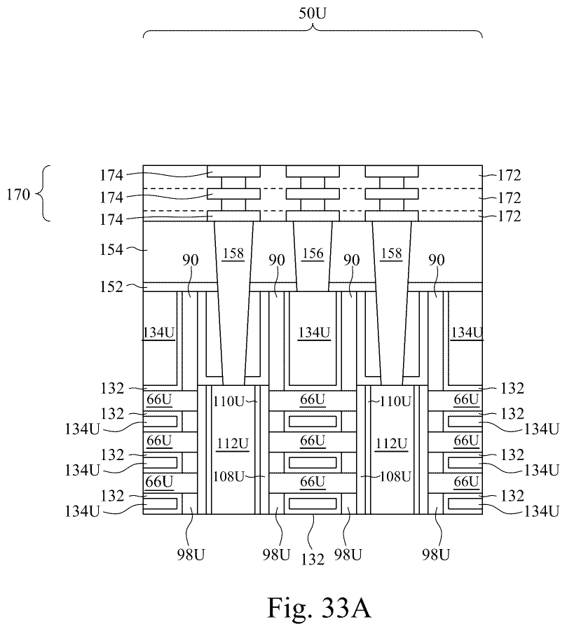

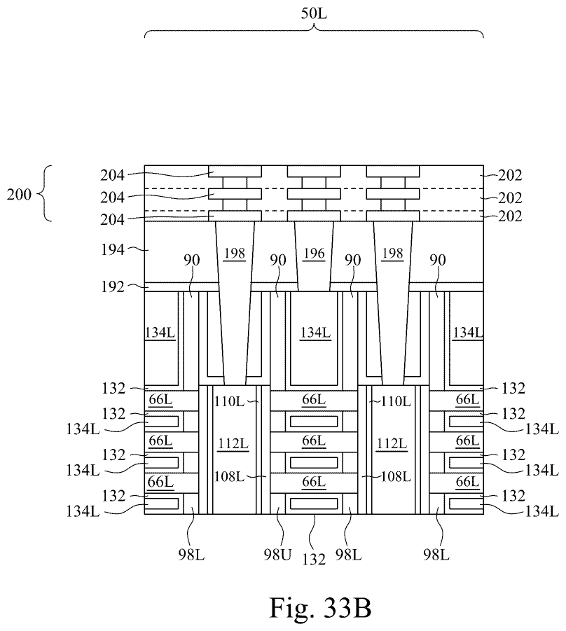

In FIGS. 33A-33B, the stop material 106 and remaining portions of the semiconductor fins 62 are removed to expose the upper source/drain contacts 112U and the lower source/drain contacts 112L of, respectively, the upper wafer 50U and the lower wafer 50L. The removal processes may be performed in a similar manner as described for FIG. 24.

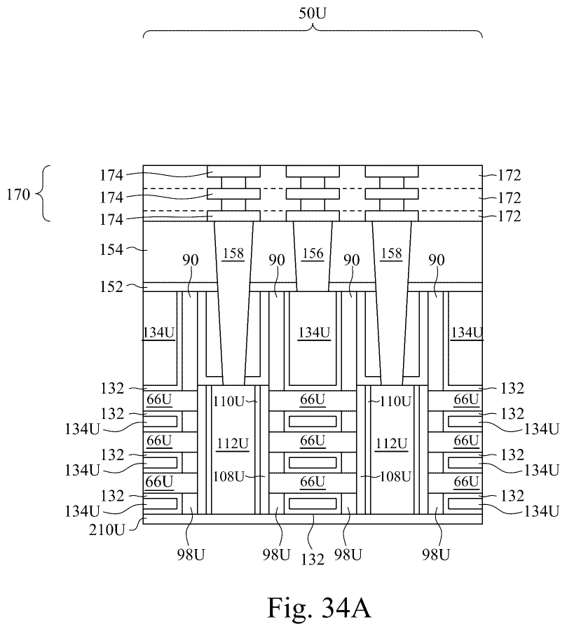

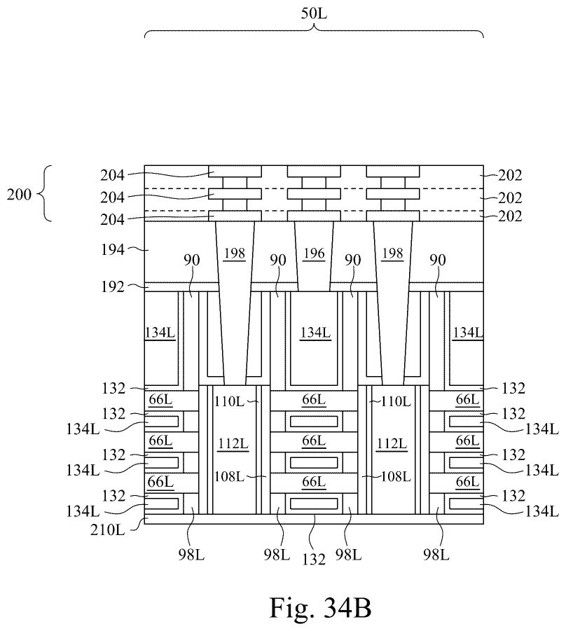

In FIGS. 34A-34B, bonding layers 210 are formed over the gate dielectrics 132, the source/drain contacts 112, the epitaxial source/drain regions 108, and the inner spacers 98 exposed by the removal of the stop material 106 and remaining portions of the semiconductor fins 62. An upper bonding layer 210U is formed for the upper wafer 50U. A lower bonding layer 210L is formed for the lower wafer 50L. In some embodiments, the bonding layers 210 are formed of silicon oxide (e.g., a high density plasma (HDP) oxide or the like) that is deposited by CVD, ALD, or the like. The bonding layers 210 may likewise include oxide layers that are formed using, for example, CVD, ALD, thermal oxidation, or the like. Other suitable materials may be used for the bonding layers 210.

In FIG. 35, the upper wafer 50U is bonded to the lower wafer 50L. The wafers may be bonded using a suitable technique such as dielectric-to-dielectric bonding, or the like. Specifically, the upper bonding layer 210U of the upper wafer 50U is bonded to the lower bonding layer 210L of the lower wafer 50L. A surface treatment may be performed on one or more of the bonding layers 210. The surface treatment may include a plasma treatment. The plasma treatment may be performed in a vacuum environment. After the plasma treatment, the surface treatment may further include performing a cleaning process (e.g., a rinse with deionized water or the like) on one or more of the bonding layers 210. The upper wafer 50U is then aligned with the lower wafer 50L and the two are pressed against each other to initiate a pre-bonding of the upper bonding layer 210U to the lower bonding layer 210L. The pre-bonding may be performed at about room temperature. After the pre-bonding, an annealing process may be performed. The bonds are strengthened by the annealing process. The bonded structure includes CFETs, including the lower nanostructure-FETs of the lower wafer 50L and the upper nanostructure-FETs of the upper wafer 50U.

Embodiments may achieve advantages. The lower source/drain contacts 112L and the upper source/drain contacts 112U occupy portions of the source/drain recesses 94 that would otherwise be occupied by epitaxial source/drain regions, which are formed of doped semiconductor materials. Thus, the lower source/drain contacts 112L and the upper source/drain contacts 112U have a large volume. The lower source/drain contacts 112L and the upper source/drain contacts 112U are formed of a metal, which has a smaller resistance than doped semiconductor materials. Forming the lower source/drain contacts 112L and the upper source/drain contacts 112U of a metal having a larger volume may decrease the parasitic resistance of the nanostructure-FETs, which may improve their performance.

In an embodiment, a device includes: a first semiconductor nanostructure; a second semiconductor nanostructure adjacent the first semiconductor nanostructure; a first source/drain region on a first sidewall of the first semiconductor nanostructure; a second source/drain region on a second sidewall of the second semiconductor nanostructure, the second source/drain region completely separated from the first source/drain region; and a source/drain contact between the first source/drain region and the second source/drain region. In some embodiments, the device further includes: a first metal-semiconductor alloy region between the first source/drain region and the source/drain contact; and a second metal-semiconductor alloy region between the second source/drain region and the source/drain contact, the second metal-semiconductor alloy region completely separated from the first metal-semiconductor alloy region. In some embodiments of the device, the first source/drain region and the second source/drain region each have an impurity concentration in a range of 10²¹ atoms/cm³ and 10²² atoms/cm³. In some embodiments, the device further includes: a dielectric layer on top surfaces of the source/drain contact, the first source/drain region, and the second source/drain region. In some embodiments, the device further includes: a source/drain via extending through the dielectric layer to contact the source/drain contact. In some embodiments of the device, the first source/drain region and the second source/drain region are p-type source/drain regions, and the source/drain contact includes tungsten, cobalt, molybdenum, or ruthenium. In some embodiments of the device, the first source/drain region and the second source/drain region are n-type source/drain regions, and the source/drain contact includes tungsten, cobalt, molybdenum, or ruthenium.

In an embodiment, a device includes: a lower transistor including: a lower semiconductor nanostructure; a lower source/drain region adjacent the lower semiconductor nanostructure; and a lower source/drain contact adjacent the lower source/drain region; an upper transistor above the lower transistor, the upper transistor including: a upper semiconductor nanostructure; a upper source/drain region adjacent the upper semiconductor nanostructure; and a upper source/drain contact adjacent the upper source/drain region; and an isolation dielectric between the lower source/drain contact and the upper source/drain contact. In some embodiments of the device, the lower source/drain contact includes a first contact material, the upper source/drain contact includes a second contact material, and the second contact material is different than the first contact material. In some embodiments of the device, the first contact material is tungsten, cobalt, molybdenum, or ruthenium, and the second contact material is tungsten, cobalt, molybdenum, or ruthenium. In some embodiments of the device, the lower source/drain contact includes a contact material, and the upper source/drain contact includes the contact material. In some embodiments, the device further includes: an isolation structure between the lower semiconductor nanostructure and the upper semiconductor nanostructure. In some embodiments of the device, the lower transistor further includes a lower gate electrode around the lower semiconductor nanostructure, and the upper transistor further includes an upper gate electrode around the upper semiconductor nanostructure. In some embodiments, the device further includes: a lower source/drain via contacting a back-side of the lower source/drain contact; and an upper source/drain via contacting a front-side of the upper source/drain contact.

In an embodiment, a method includes: forming a recess in a first semiconductor nanostructure; forming a stop material in the recess; growing a first epitaxial source/drain region on the stop material and in the recess, the first epitaxial source/drain region disposed on a sidewall of the first semiconductor nanostructure; forming a first source/drain contact on the stop material and in the recess, the first source/drain contact disposed on a sidewall of the first epitaxial source/drain region; and forming an isolation dielectric on the first source/drain contact. In some embodiments of the method, growth of the first epitaxial source/drain region is stopped before adjoining growth merges together in the recess. In some embodiments, the method further includes: forming the recess in a second semiconductor nanostructure; and forming a dummy spacer on a sidewall of the second semiconductor nanostructure, the dummy spacer masking the sidewall of the second semiconductor nanostructure when growing the first epitaxial source/drain region. In some embodiments, the method further includes: forming the recess in a second semiconductor nanostructure; growing a second epitaxial source/drain region on the isolation dielectric and in the recess, the second epitaxial source/drain region disposed on a sidewall of the second semiconductor nanostructure; forming a second source/drain contact on the isolation dielectric and in the recess, the second source/drain contact disposed on a sidewall of the second epitaxial source/drain region; and forming an inter-layer dielectric on the second source/drain contact. In some embodiments of the method, the first source/drain contact is formed of a first contact material, the second source/drain contact is formed of a second contact material, and the second contact material is different than the first contact material. In some embodiments of the method, the first source/drain contact is formed of a contact material, and the second source/drain contact is formed of the contact material.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device comprising:
a first channel region;
a first source/drain region adjacent the first channel region;
a source/drain contact adjacent the first source/drain region;
a second source/drain region adjacent the source/drain contact, the second source/drain region completely separated from the first source/drain region; and
a second channel region adjacent the second source/drain region, wherein a line extending from the first channel region to the second channel region intersects each of the first source/drain region, the source/drain contact, and the second source/drain region.

2. The device of claim 1, further comprising:
a first metal-semiconductor alloy region between the first source/drain region and the source/drain contact; and
a second metal-semiconductor alloy region between the second source/drain region and the source/drain contact, the second metal-semiconductor alloy region completely separated from the first metal-semiconductor alloy region, the line intersecting each of the first metal-semiconductor alloy region and the second metal-semiconductor alloy region.

3. The device of claim 1, further comprising:
an isolation dielectric extending across each of the first source/drain region, the source/drain contact, and the second source/drain region.

4. The device of claim 1, wherein the first source/drain region and the second source/drain region have a same conductivity type.

5. The device of claim 1, wherein the source/drain contact has greater width along the line than the first source/drain region and the second source/drain region.

6. The device of claim 1, wherein the source/drain contact has greater volume than the first source/drain region and the second source/drain region.

7. A device comprising:
a first interconnect structure comprising a first conductive feature;
a second interconnect structure comprising a second conductive feature; and
a device layer between the first interconnect structure and the second interconnect structure, the device layer comprising:
a first transistor comprising a first channel region, a first source/drain region adjacent the first channel region, and a first source/drain contact coupling the first source/drain region to the first conductive feature;
a second transistor comprising a second channel region, a second source/drain region adjacent the second channel region, and a second source/drain contact coupling the second source/drain region to the second conductive feature; and
an isolation dielectric extending between the first source/drain contact and the second source/drain contact.

8. The device of claim 7, wherein the isolation dielectric extends between the first source/drain region and the second source/drain region.

9. The device of claim 7, wherein the first transistor further comprises a first metal-semiconductor alloy region between the first source/drain contact and the first source/drain region, the second transistor further comprises a second metal-semiconductor alloy region between the second source/drain contact and the second source/drain region, and the isolation dielectric extends between the first metal-semiconductor alloy region and the second metal-semiconductor alloy region.

10. The device of claim 7, wherein the first channel region comprises a plurality of first semiconductor nanostructures, and the second channel region comprises a plurality of second semiconductor nanostructures.

11. The device of claim 10, wherein the first transistor further comprises a first gate structure surrounding each of the first semiconductor nanostructures, and the second transistor further comprises a second gate structure surrounding each of the second semiconductor nanostructures.

12. The device of claim 11, wherein the device layer further comprises:
an isolation structure adjacent the isolation dielectric, the isolation structure disposed between the first gate structure and the second gate structure.

13. The device of claim 11, wherein the device layer further comprises:
a first spacer between the first gate structure and the first source/drain region; and
a second spacer between the second gate structure and the second source/drain region.

14. The device of claim 7, wherein the first conductive feature is a first level conductive line of the first interconnect structure, the second conductive feature is a power rail, and a width of the power rail is larger than a width of the first level conductive line.

15. A device comprising:
a first transistor comprising a first semiconductor nanostructure, a first source/drain region adjacent the first semiconductor nanostructure, and a first source/drain contact adjacent the first source/drain region;
a second transistor comprising a second semiconductor nanostructure, a second source/drain region adjacent the second semiconductor nanostructure, and a second source/drain contact adjacent the second source/drain region;
a first dielectric layer extending continually across an upper surface of the first source/drain contact, an upper surface of the first source/drain region, a lower surface of the second source/drain contact, and a lower surface of the second source/drain region; and
a second dielectric layer extending continually across the upper surface of the first source/drain region, an upper surface of the first semiconductor nanostructure, the lower surface of the second source/drain region, and a lower surface of the second semiconductor nanostructure.

16. The device of claim 15, wherein the first source/drain contact has a greater volume than the first source/drain region, and the second source/drain contact has a greater volume than the second source/drain region.

17. The device of claim 15, wherein the first source/drain contact comprises a first contact material, the second source/drain contact comprises a second contact material, and the second contact material is different than the first contact material.

18. The device of claim 15, wherein the first source/drain contact and the second source/drain contact each comprise a same contact material.

19. The device of claim 15, further comprising:
a first metal-semiconductor alloy region between the first source/drain region and the first source/drain contact, the first dielectric layer also extending across an upper surface of the first metal-semiconductor alloy region; and
a second metal-semiconductor alloy region between the second source/drain region and the second source/drain contact, the first dielectric layer also extending across a lower surface of the second metal-semiconductor alloy region.

20. The device of claim 15, wherein the first transistor has a first conductivity type, the second transistor has a second conductivity type, and the second conductivity type is opposite the first conductivity type.
